(19) United States
(12) Patent Application Publication
(10) Pub. No.: US 2003/0222303 A1
(43) Pub. Date: Dec. 4, 2003

(54) Non-volatile semiconductor memory device and method for fabricating the same

(75) Inventors: Masatoshi Fukuda, Kawasaki (JP); Taro Sugizaki, Kawasaki (JP); Toshiro Nakanishi, Kawasaki (JP); Yasuo Nara, Kawasaki (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: FUJITSU LIMITED, Kawasaki (JP)

(21) Appl. No.: 10/449,414

(22) Filed: Jun. 2, 2003

(30) Foreign Application Priority Data
May 31, 2002 (JP) 2002-158891
May 9, 2003 (JP) 2003-132041

(51) Int. Cl. H01L 29/76; H01L 29/788

(52) U.S. Cl. 257/321; 257/314; 257/315; 257/317; 257/326

(57) ABSTRACT

A non-volatile semiconductor memory device comprise a source region 44 and a drain region 46 formed in a semiconductor substrate 30; a gate electrode 36 formed on the semiconductor substrate between the source region and the drain region with a first insulation film 32 formed between the gate electrode and the semiconductor substrate; and a charge accumulation region 42a, 42b of a dielectric material, which is formed on at least either of the side wall of the gate electrode on the side of the source region and the side wall of the gate electrode on the side of the drain region. Accordingly, charges accumulated on the side of the source region 44 and the charges accumulated on the side of the drain region 46 can be easily spatially isolated from each other.

### CROSS-REFERENCE TO RELATED APPLICATION

This application is based upon and claims priority of Japanese Patent Application No. 2002-158891, filed on May 31, 2002, and Japanese Patent Application No. 2003-132041, filed on May 9, 2003, the contents being incorporated herein by reference.

### BACKGROUND OF THE INVENTION

The present invention relates to a non-volatile semiconductor memory, more specifically to a non-volatile semiconductor memory which stores information by accumulating charges in the charge accumulation layer of an insulation layer, and the method for fabricating the non-volatile semiconductor memory.

As erasable non-volatile semiconductor memories are generally known EEPROM and flash EEPROM, which accumulate charges in the floating gates to store information. These non-volatile semiconductor memories require floating gates for storing information in addition to control gates which function as word lines, and accordingly require two conductor layers to constitute memory cell transistors. On the other hand, as a structure which is simple and easy to be highly integrated is proposed a non-volatile semiconductor memory having memory cell transistors whose gates are formed of a single layer by using a dielectric film as the charge accumulation layer.

As the non-volatile semiconductor memory having the single-layer gates, non-volatile semiconductor memory which uses, e.g., the SiO₂/SiN/SiO₂ structure as the charge accumulation layer and holds charges in defects of the SiN has been developed (see patent reference 1 and 2). For higher integration and lower costs, a non-volatile semiconductor memory of 2-bit operation which can locally hold charges respectively at the end of the source and the end of the drain is developed.

The non-volatile semiconductor memory of 2-bit operation has an advantage that a number of storage memories is simply doubled for the same number of cells, and an advantage that a chip surface can be simply halved for the same number of storage memories. The non-volatile semiconductor memory of 2-bit operation is a very prospective device which can satisfy the requirements of higher integration and lower costs.

A technique which is applicable to the micronization of such non-volatile semiconductor device is the micronization technique of logic transistors. In the logic devices, about 0.03 μm transistors have been presently developed. By using the fabrication technique of this generation, structures of the non-volatile semiconductor memory device having an about 0.03 μm-gate width can be formed.

### Patent Reference 1

Specification of U.S. Pat. No. 5,768,192

### Patent Reference 2

Specification of Japanese Patent Laid-Open Publication No. 2001-118943

### Patent Reference 3

Specification of Japanese Patent Laid-Open Publication No. 2001-77219

### Patent Reference 4

Specification of Japanese Patent Laid-Open Publication No. Hei 7-211809

However, in such micronized cells, the gate insulation film as well must be thinned based on the scaling rule, which will deteriorate the charge holding characteristics. The accordingly decreased gate length makes it difficult to isolate accumulated charges near the end of the source and accumulated charges near the end of the drain. It is difficult to ensure the 2-bit operation.

### SUMMARY OF THE INVENTION

An object of the present invention is to provide a non-volatile semiconductor memory device and a method for fabricating the non-volatile semiconductor memory device which can improve the charge holding characteristics.

Another object of the present invention is to provide a non-volatile semiconductor memory device which can ensure the isolation of the accumulated charges in the 2-bit operation.

According to one aspect of the present invention, there is provided a non-volatile semiconductor memory device comprising: a source region and a drain region formed in a semiconductor substrate; a gate electrode formed on the semiconductor substrate between the source region and the drain region with a first insulation film formed between the gate electrode and the semiconductor substrate; and a charge accumulation region of a dielectric material, which is formed on at least either of the side wall of the gate electrode on the side of the source region and the side wall of the gate electrode on the side of the drain region.

According to another aspect of the present invention, there is provided a method for fabricating a non-volatile semiconductor memory device comprising the steps of: forming a first insulation film on a semiconductor substrate; forming a gate electrode on the first insulation film; forming charge accumulation regions of a dielectric material respectively on a pair of side walls of the gate electrode opposed to each other; and implanting a dopant into the semiconductor substrate with the gate electrode and the charge accumulation regions as a mask to form a source region and a drain region with the ends of junctions thereof on the side of the gate electrode being spaced from a region of the semiconductor substrate immediately below the gate electrode.

As described above, according to the present invention, the sidewall charge accumulation layers are formed on the side wall of the gate electrode on the side of the source region and on the side wall of the gate electrode on the side of the drain region so as to accumulate charges in the sidewall charge accumulation layers to store required information. Charge holding characteristics can be improved.

As described above, according to the present invention, the sidewall charge accumulation layers are formed respectively on the side wall of the gate electrode on the side of the source region and the side wall thereof on the side of the drain region, and the sidewall charge accumulation layers accumulate charges to store required information, whereby a charge accumulated on the side of the source region and a charge accumulated on the side of the drain region can be easily isolated from each other. Accordingly, even with a very short gate length, the 2-bit operation can be ensured. The insulation film has a smaller thickness between the substrate and the sidewall accumulation layers than between the substrate and the gate electrode, whereby characteristics of writing in the sidewall charge accumulation layers can be improved.

### BRIEF DESCRIPTION OF THE DRAWINGS

FIG. 1 is a diagrammatic sectional view of the non-volatile semiconductor memory device according to the present invention, which shows the basic structure thereof.

FIG. 2 is a diagrammatic sectional view of the structure used in a simulation with physical parameters.

FIG. 3 is a graph of Id-Vg characteristics of the non-volatile semiconductor memory device shown in FIG. 2 given by the simulation.

FIG. 4 is a graph of influences on the Id-Vg characteristics of the charge accumulation regions of the non-volatile semiconductor memory device shown in FIG. 2, which were given by a simulation.

FIG. 5 is a diagrammatic sectional view of the non-volatile semiconductor memory device according to a first embodiment of the present invention, which shows a structure thereof.

FIGS. 6A to 6C are sectional views of the non-volatile semiconductor memory device according to the first embodiment in the steps of the method for fabricating the same, which explain the method (Part 1).

FIGS. 7A to 7C are sectional views of the non-volatile semiconductor memory device according to the first embodiment in the steps of the method for fabricating the same, which explain the method (Part 2).

FIGS. 8A and 8B are sectional views of the non-volatile semiconductor memory device according to the first embodiment in the steps of the method for fabricating the same, which explain the method (Part 3).

FIGS. 9A and 9B are sectional views of the non-volatile semiconductor memory device according to the first embodiment in the steps of the method for fabricating the same, which explain the method (Part 4).

FIG. 10 is a diagrammatic sectional view of the non-volatile semiconductor memory device according to a second embodiment of the present invention, which shows a structure thereof.

FIGS. 11A to 11C are sectional views of the non-volatile semiconductor memory device according to the second embodiment in the steps of the method for fabricating the same, which explain the method (Part 1).

FIGS. 12A and 12B are sectional views of the non-volatile semiconductor memory device according to the second embodiment in the steps of the method for fabricating the same, which explain the method (Part 2).

FIG. 13 is a graph of relationships between positions of the ends of the junctions of the source region and drain region on the side of the gate electrode, and threshold voltages.

FIG. 14 is a graph of the results of the actual measurement of Id-Vg characteristics of the non-volatile semiconductor memory device.

FIG. 15 is a sectional view of the non-volatile semiconductor memory device according to a third embodiment of the present invention.

FIGS. 16A and 16B are sectional views of the non-volatile semiconductor memory device according to the third embodiment of the present invention in the steps of the method for fabricating the same, which show the method (Part 1).

FIGS. 17A and 17B are sectional views of the non-volatile semiconductor memory device according to the third embodiment of the present invention in the steps of the method for fabricating the same, which show the method (Part 2).

FIGS. 18A and 18B are sectional views of the non-volatile semiconductor memory device according to the third embodiment of the present invention in the steps of the method for fabricating the same, which show the method (Part 3).

FIGS. 19A and 19B are sectional views of the non-volatile semiconductor memory device according to the third embodiment of the present invention in the steps of the method for fabricating the same, which show the method (Part 4).

FIGS. 20A and 20B are sectional views of the non-volatile semiconductor memory device according to the third embodiment of the present invention in the steps of the method for fabricating the same, which show the method (Part 5).

FIGS. 21A and 21B are sectional views of the non-volatile semiconductor memory device according to the third embodiment of the present invention in the steps of the method for fabricating the same, which show the method (Part 6).

FIGS. 22A and 22B are sectional views of the non-volatile semiconductor memory device according to the third embodiment of the present invention in the steps of the method for fabricating the same, which show the method (Part 7).

FIGS. 23A and 23B are sectional views of the non-volatile semiconductor memory device according to the third embodiment of the present invention in the steps of the method for fabricating the same, which show the method (Part 8).

FIGS. 24A and 24B are sectional views of the non-volatile semiconductor memory device according to the third embodiment of the present invention in the steps of the method for fabricating the same, which show the method (Part 9).

FIGS. 25A and 25B are sectional views of the non-volatile semiconductor memory device according to the third embodiment of the present invention in the steps of the method for fabricating the same, which show the method (Part 10).

FIGS. 26A and 26B are sectional views of the non-volatile semiconductor memory device according to the third embodiment of the present invention in the steps of the method for fabricating the same, which show the method (Part 11).

FIGS. 27A and 27B are sectional views of the non-volatile semiconductor memory device according to the third embodiment of the present invention in the steps of the method for fabricating the same, which show the method (Part 12).

FIGS. 28A and 28B are sectional views of the non-volatile semiconductor memory device according to one modification of the third embodiment of the present invention in the step so the method for fabricating the same, which explain the method (Part 1).

FIGS. 29A and 29B are sectional views of the non-volatile semiconductor memory device according to one modification of the third embodiment of the present invention in the step so the method for fabricating the same, which explain the method (Part 2).

FIGS. 30A and 30B are sectional views of the non-volatile semiconductor memory device according to one modification of the third embodiment of the present invention in the step so the method for fabricating the same, which explain the method (Part 3).

FIGS. 31A and 31B are sectional views of the non-volatile semiconductor memory device according to one modification of the third embodiment of the present invention in the step so the method for fabricating the same, which explain the method (Part 4).

FIG. 32 is a sectional view of the non-volatile semiconductor memory device according to a fourth embodiment of the present invention.

FIGS. 33A and 33B are sectional views of the non-volatile semiconductor memory device according to the fourth embodiment of the present invention in the steps of the method for fabricating the same, which show the method (Part 1).

FIGS. 34A and 34B are sectional views of the non-volatile semiconductor memory device according to the fourth embodiment of the present invention in the steps of the method for fabricating the same, which show the method (Part 2).

FIGS. 35A and 35B are sectional views of the non-volatile semiconductor memory device according to the fourth embodiment of the present invention in the steps of the method for fabricating the same, which show the method (Part 3).

FIGS. 36A and 36B are sectional views of the non-volatile semiconductor memory device according to the fourth embodiment of the present invention in the steps of the method for fabricating the same, which show the method (Part 4).

FIG. 37 is a sectional view of the non-volatile semiconductor memory device according to a fifth embodiment of the present invention.

FIGS. 38A and 38B are sectional views of the non-volatile semiconductor memory device according to the fifth embodiment of the present invention in the steps of the method for fabricating the same, which show the method.

FIGS. 39A and 39B are sectional views of the non-volatile semiconductor memory device according to a modification of the present invention in the steps of the method for fabricating the same, which show the method.

### DETAILED DESCRIPTION OF THE INVENTION

[Principle of the Present Invention]

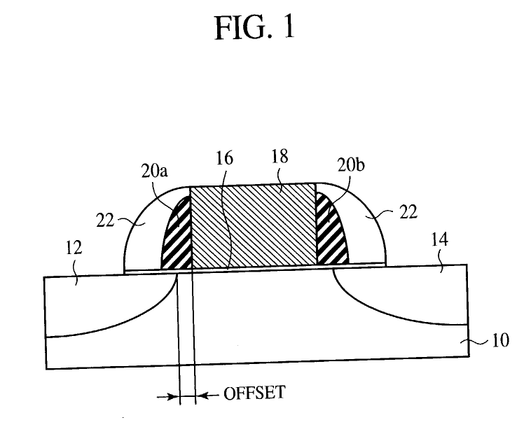

First, the basic structure of the non-volatile semiconductor memory device according to the present invention will be explained with reference to FIG. 1.

A source region 12 and a drain region 14 are formed on a semiconductor substrate 10. A gate electrode 18 is formed on the semiconductor substrate 10 between the source region 12 and the drain region 14 with a gate insulation film 16 formed between the semiconductor substrate 10 and the gate electrode 18. A sidewall charge accumulation layers 20a, 20b of a dielectric film are formed respectively on the side wall of the source region 12 on the side of the gate electrode 18 and the side wall of the drain region 14 on the side of the gate electrode 18. The ends of the junctions of the source region 12 and the drain region 14 on the side of the gate electrode 18 are not extended to the region below the gate electrode 18 but are positioned regions below the sidewall charge accumulation layers 20a, 20b. That is, offsets are provided between the gate electrode 18 and the ends of the junctions of the source region 12 and the drain region 14 on the side of the gate electrode 18. A sidewall insulation film 22 is formed on the side walls of the gate electrode 18 where the sidewall charge accumulation layers 20a, 20b are formed.

As described above, the non-volatile semiconductor memory device according to the present invention is characterized mainly in that the sidewall charge accumulation layers 20a, 20b are formed on the side walls of the gate electrode 18. The non-volatile semiconductor memory device is thus constituted, whereby charges accumulated on the side of the source region 12 and charges accumulated on the side of the drain region 14 can be accumulated in the discrete sidewall charge accumulation layers 20 formed spaced from each other with the gate electrode 18 formed therebetween. Accordingly, charges accumulated on the side of the source region 12 and charges accumulated on the side of the drain region 14 can be easily isolated from each other. Thus, even with a very short gate length, 2-bit operation can be ensured.

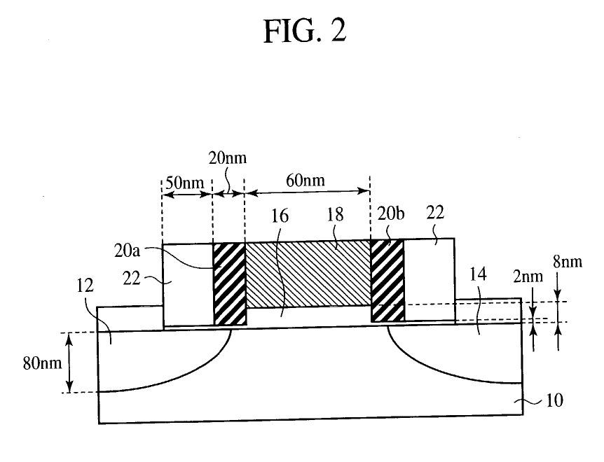

Next, the operation and advantageous effects of the non-volatile semiconductor memory device shown in FIG. 1 will be explained by means of results of a simulation. In the simulation, as shown in FIG. 2, a junction depth of the source region 12 and the drain region 14 was 80 nm; a film thickness of the gate insulation film 16 below the gate electrode 18 was 8 nm; a film thickness of the gate insulation film 16 below the sidewall charge accumulation layer 20 was 2 nm; a width of the sidewall charge accumulation layer 20 was 20 nm; and a width of the sidewall insulation film 22 was 50 nm. A sectional shape of the sidewall charge accumulation layer 20 and the sidewall insulation film 22 were assumed to be rectangular.

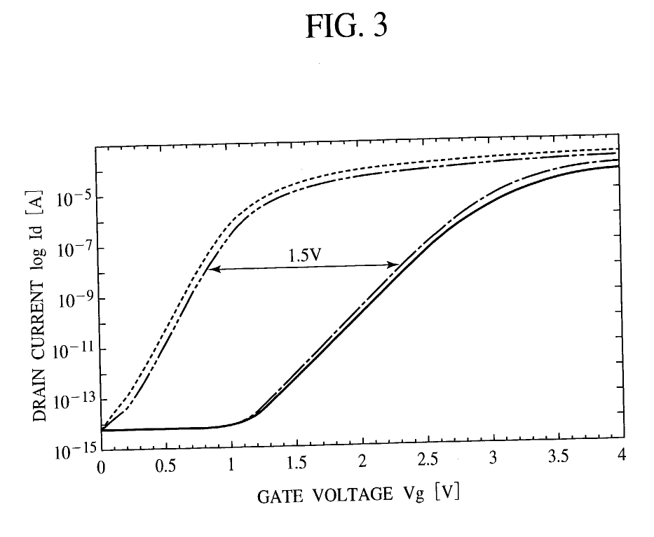

FIG. 3 is a graph of Id-Vg characteristics of the non-volatile semiconductor memory shown in FIG. 2 given by the simulation. In FIG. 3, the dot line indicates the case that no charge was accumulated in either of the sidewall charge accumulation layer 20a and the sidewall charge accumulation layer 20b. The one-dotline indicates the case that a 8×10¹⁸ cm⁻³ charge was accumulated in either of the sidewall charge accumulation layer 20a and the sidewall charge accumulation layer 20b, and a bias was forwardly applied. The two-dot line indicates the case that a 8×10¹⁸ cm⁻³ charge was accumulated in either of the sidewall charge accumulation layer 20a and the sidewall charge accumulation layer 20b, and a bias was reversely applied. The solid line indicates the case that a 8×10¹⁸ cm⁻³ charge was accumulated respectively in both of the sidewall charge accumulation layers 20a, 20b.

The case that a bias was forwardly applied means that charges were accumulated in the sidewall charge accumulation layer 20a, and a higher voltage was applied to the drain region 14 than to the source region 12 or the case that charges were accumulated in the sidewall charge accumulation layer 20b, and a higher voltage was applied to the source region 12 than to the drain region 14. The case that a bias was reversely applied means that charges were accumulated in the sidewall charge accumulation layer 20b, and a higher voltage was applied to the drain region 14 than to the source region 12 or the case that charges were accumulated in the sidewall charge accumulation layer 20a, and a higher voltage was applied to the source region 12 than to the drain region 14.

As shown, the case that charges were accumulated respectively in both the sidewall charge accumulation layers 20a, 20b, and the case that charges were accumulated in either of the sidewall charge accumulation layer 20a and the sidewall charge accumulation layer 20b, and a bias was forwardly applied have substantially the same Id-Vg characteristics, and has an about 1.5 V threshold voltage shift in comparison with the case that no charge was accumulated in either of the sidewall charge accumulation layers 20a, 20b. Accordingly, the absence and presence of the accumulated charges can be confirmed by drain current changes based on a threshold voltage of the transistor.

The cases that charges were accumulated in either of the sidewall charge accumulation layers 20a, 20b, and a bias was reversely applied, and the case that no charge was accumulated in either of the sidewall charge accumulation layers 20a, 20b have substantially the same Id-Vg characteristics. Accordingly, when a drain current is changed by changing a direction of a bias to be applied between the source region 12 and the drain region 14, it is confirmed that charges are accumulated in either of the sidewall charge accumulation layers 20a, 20b. In which of the sidewall charge accumulation layers 20a, 20b charges are accumulated can be confirmed by a direction of a bias to be applied.

As described above, the non-volatile semiconductor memory device according to the present invention can read out the respective four states necessary for the 2-bit operation. In the 2-bit operation, an about 1.5 V threshold voltage is ensured, and is found to be of practical level.

In order to realize the Id-Vg characteristics shown in FIG. 3, it is very important to position the ends of the junctions of the source region 12 and the drain region 14 on the side of the gate electrode 18 from a region below the sidewall charge accumulation layers 20a, 20b to a region below the sidewall insulation film 22 in addition to forming the sidewall charge accumulation layers 20a, 20b on the side walls of the gate electrode 18.

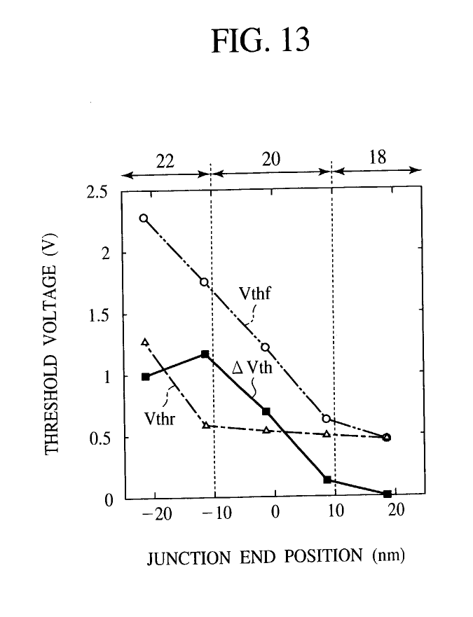

FIG. 13 is a graph of relationships between threshold voltages and positions of the ends of the junctions of the source region and the drain region on the side of the gate electrode. The positions of the ends of the junctions of the source region and the drain region on the side of the gate electrode are taken on the horizontal axis. The threshold voltages are taken on the vertical axis. In the graph, the two-dot line indicate the threshold voltages Vthf when a bias is applied forward. The one-dot line indicates the threshold voltages when a bias is reversely applied. The solid line indicates differences ΔVth between the threshold voltages Vthf given when the bias is applied forward and the threshold voltages Vthf given when the bias is applied reversely.

As seen in FIG. 13, when the ends of the junctions of the source region 12 and the drain region 14 on the side of the gate electrode 18 are positioned in the regions below the gate electrode 18, both the threshold voltage Vthf and the threshold voltage Vthr are low, and the difference ΔVth between the two is small.

As the ends of the junctions of the source region 12 and the drain region 14 on the side of the gate electrode 18 are remoter from the gate electrode 18, the threshold voltage Vthf given when the bias is applied forward tends to be higher. On the other hand, when the bias is applied reversely, the threshold voltage Vthr does not substantially change even when the ends of the junctions of the source region 12 and the drain region 14 on the side of the gate electrode 18 are remote from the gate electrode 18. Accordingly, the threshold voltage difference ΔVth tends to be larger as the ends of the junctions of the source region 12 and the drain region 14 on the side of the gate electrode 18 are remoter from the gate electrode 18.

However, the threshold voltage Vthr given when the bias is applied reversely tends to abruptly increase when the ends of the junctions of the source region 12 and the drain region 14 on the side of the gate electrode 18 are too remote from the gate electrode 18. Thus, the threshold difference ΔVth becomes smaller when the ends of the junctions of the source region 12 and the drain region 14 on the side of the gate electrode 18 are too remote from the gate electrode 18.

Based on the above, it is found very important to arrange the ends of the junctions of the source region 12 and the drain region 14 on the side of the gate electrode 18 at suitable positions.

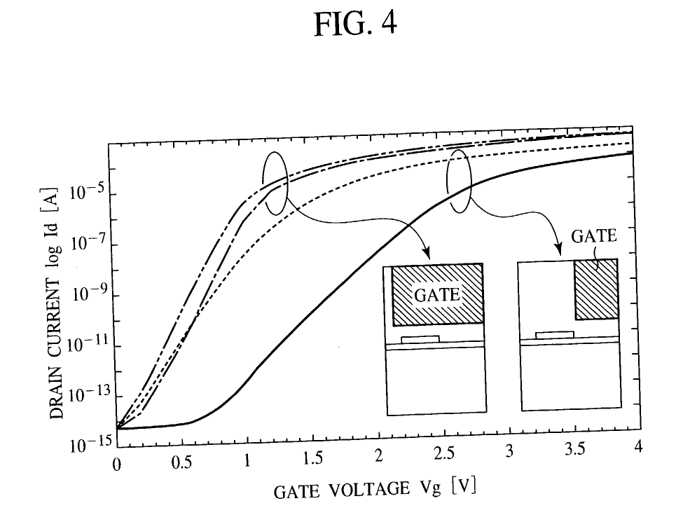

FIG. 4 is a graph of influences on the Id-Vg characteristics of the charge accumulation regions, which were given by a simulation. In this simulation, Id-Vg characteristics in the charge accumulated state and the no charge accumulated state were computed by changing a gate length with the positions of the source/drain regions and of the charge accumulation regions fixed, for the state that the charge accumulation regions are positioned outside the gate electrode and the state that the charge accumulation regions are positioned below the gate electrode.

In FIG. 4, the solid line indicates the case that the charge accumulation regions are positioned in regions outer of the gate electrode, and charges are accumulated. The dot line indicates that the charge accumulation regions are positioned in regions outer of the gate electrode, and no charge is accumulated. The one-dot chain line indicates the case that the charge accumulation regions are positioned in a region below the gate electrode, and charges are accumulated. The two-dot chain line indicates that the charge accumulation regions are positioned below the gate electrode, and no charge is accumulated. It was assumed that in the charge accumulated state, the 3 nm×20 nm charge accumulated regions were provided on the source region side and the drain region side, and a 8×10¹⁸ cm⁻³ charge was accumulated in the respective charge accumulation regions.

As shown in FIG. 4, when the charge accumulation region is in a region outer of the gate electrode, a threshold voltage shift is about 1 V, which enables the memory operation. When the charge accumulation region is positioned in a region below the gate electrode, a threshold voltage shift was only about 0.1 V, which disables the memory operation.

Thus, in order to obtain a sufficient threshold voltage in the no charge accumulation state and the charge accumulation state it is very important to position the charge accumulation regions outer of the gate electrode.

In electron introducing channel hot electrons into the charge accumulation layers, the hot electrons are generated at the junctions between the source/drain regions and the semiconductor substrate on the side of the channel. That is, the efficiency of introducing electrons into the charge accumulation layers is highest near the junctions between the source/drain regions and the semiconductor substrate. Accordingly, in order to position the charge accumulation regions in regions outer of the gate electrode, the source/drain regions can be formed with the ends of the junctions of the source/drain regions on the side of the gate electrode positioned in regions outer of the gate electrode.

It is effective for higher write characteristics that as shown in FIG. 2, the gate insulation film 16 has a film thickness which is smaller below the gate electrode 18 than below the sidewall charge accumulation layer 20. The gate insulation film 16 has a decreased film thickness below the sidewall charge accumulation layer 20, and the sidewall charge accumulation layer 20 is formed of a material, such as silicon nitride film, which has a higher dielectric constant than that of the gate insulation film of an insulation film of the silicon oxide group, whereby the electric fields in the charge accumulation regions can be stronger. Therefore, the efficiency of introducing electron into the charge accumulation layers can be improved.

### A Firs Embodiment

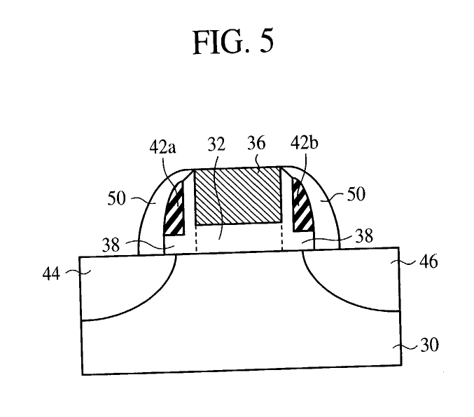

The non-volatile semiconductor memory device according to a first embodiment of the present invention and the method for fabricating the non-volatile semiconductor memory device will be explained with reference to FIGS. 5 to 9B.

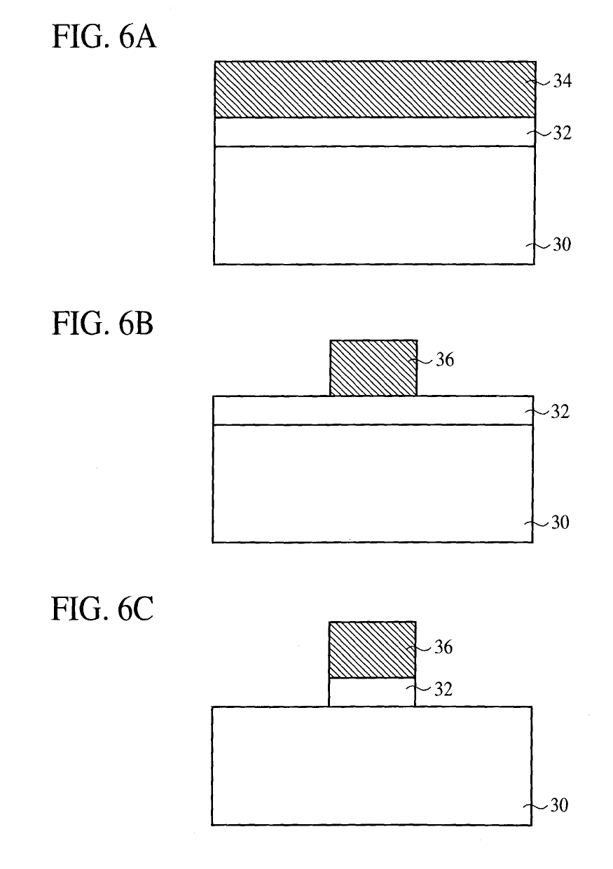

FIG. 5 is a diagrammatic sectional view of the non-volatile semiconductor memory device according to the present embodiment, which shows a structure thereof. FIGS. 6A to 9B are sectional views of the non-volatile semiconductor memory device according to the present embodiment in the steps of the method for fabricating the same, which explain the method.

First, the structure of the non-volatile semiconductor memory device according to the present embodiment will be explained with reference to FIG. 5.

A source region 44 and a drain region 46 are formed on a p type silicon substrate 30. A gate electrode 36 is formed on the silicon substrate 30 between the source region 44 and the drain region 46 with a gate insulation film 32 formed between the silicon substrate 30 and the gate electrode 36. An insulation film 38 of a silicon oxide film which is thinner than the gate insulation film 32 is formed on the gate electrode 36 and on the silicon substrate 30 in the region where the gate electrode 36 is not formed. Sidewall charge accumulation layers 42a, 42b are formed respectively on the side walls of the gate electrode 36 on the side of the source region 44 and the side walls of the gate electrode 36 on the side of the source region 46 with the insulation film 38 disposed between the side walls of the gate electrode 36, and the source and the drain regions 44, 46. A sidewall insulation film 50 is formed on the side walls of the gate electrode 36 with the sidewall charge accumulation layers 42a, 42b formed on. The ends of the junctions of the source region 44 and the drain region 46 are not extended to a region below the gate electrode 36 but are positioned from regions below the sidewall charge accumulation layers 42a, 42b to regions below the sidewall insulation film 50.

As described above, the non-volatile semiconductor memory device according to the present embodiment is mainly characterized in that the sidewall charge accumulating layers 42a, 42b are formed on the side walls of the gate electrode 36. The non-volatile semiconductor memory device having such structure can accumulate charges on the side of the source region 44 and charges on the side of the drain region 46 in the side wall charge accumulation layers 42 spaced from each other by the gate electrode 36, whereby the charge holding characteristics can be improved. Furthermore, the non-volatile semiconductor memory device is thus constituted, whereby charges accumulated on the side of the source region 44 and the charges accumulated on the side of the drain region 46 are can be accumulated in the discrete sidewall charge accumulation layers 42 spaced from each other with the gate electrode 36 therebetween, and accordingly charges accumulated on the side of the source region 44 and charges accumulated on the side of the drain region 46 can be easily isolated from each other. Resultantly, even with a very short gate length, the 2-bit operation can be ensured.

In the non-volatile semiconductor memory device according to the present embodiment, the insulation film 38 formed between the sidewall charge accumulation layer 42 and the silicon substrate 30 is thinner than the gate insulation film 32 formed between the silicon substrate 30 and the gate electrode 36, whereby the field strength of the charge accumulation regions can be increased, and the characteristics of writing in the sidewall charge accumulation layer can be improved.

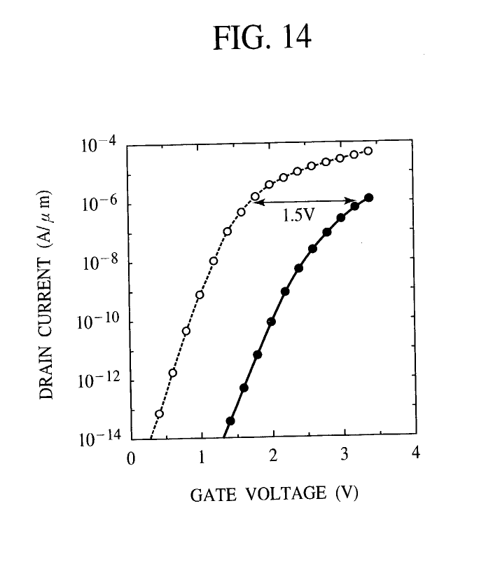

FIG. 14 is a graph of the result given by actually measuring the Id-Vg characteristics of the non-volatile semiconductor memory device shown in FIG. 5. Gate voltages are taken on the horizontal axis. Drain currents are taken on the vertical axis. In the graph, the dot line indicates that no charge is accumulated in either of the sidewall charge accumulation layers 42a, 42b. The solid line indicates that charges are accumulated in both of the sidewall accumulation layers 42a, 42b. The film thickness of the gate insulation film 32 was 6.8 nm, and the gate length was 0.4 μm. The thickness of the insulation film 38 was 4 nm, the film thickness of the sidewall charge accumulation layer 42 was 20 nm, and the film thickness of the sidewall insulation film was 60 nm. To accumulate charges in the sidewall charge accumulation layer 42a, 4V was applied to the gate electrode 36 and the drain region 46, and the voltage of the source region 44 was 0V. To read information written in the sidewall charge accumulation layer 42a, 1.2 V was applied to the gate electrode 36, and the bias applied between the source region 12 and the drain region 14 was 1.2 V.

As seen in the graph, when charges were accumulated both in the sidewall charge accumulation layers 42a, 42b, an about 1.5 V shift of the threshold voltage was obtained in comparison with that of the case that no charge was accumulated in either of the sidewall charge accumulation layers 42a, 42b. Accordingly, it is found that the absence/presence of charges accumulated in the sidewall charge accumulation layer 42, based on drain current changes which are based on a threshold voltage of the transistors.

The result of the measurement shows that the device can operate without failure even with the thickness of the insulation film 38 set thin at 4 nm.

Next, the method for fabricating the non-volatile semiconductor memory device according to the present embodiment will be explained with reference to FIGS. 6A to 9B.

First, the surface of the p type silicon substrate 30 is oxidized by, e.g., thermal oxidation to form the gate insulation film 32 of, e.g., 8 nm-thickness silicon oxide film.

Next, a 180 nm-thickness n⁺ type polycrystal silicon film 34, for example, is formed on the gate insulation film 32 (FIG. 6A). The polycrystal silicon film 34 may be formed by depositing an n⁺ type polycrystal silicon film by CVD or by depositing a non-doped polycrystal silicon film and implanting an n type dopant thereinto.

Then, the polycrystal silicon film is patterned by lithography and dry etching to form the gate electrode 36 of the polycrystal silicon film (FIG. 6B).

The gate electrode 36 can have not only the single layer structure of polycrystal silicon but also a polycide structure, polymetal structure, a metal gate structure or other structures.

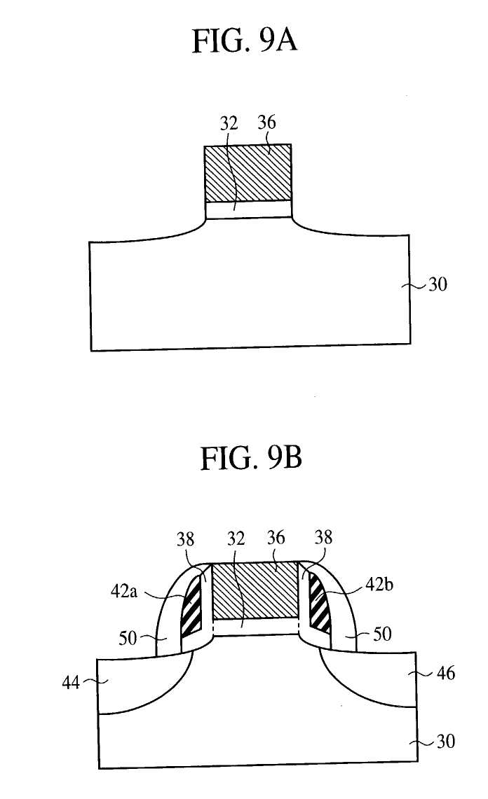

Then, the gate insulation film 32 is etched by dry etching or wet etching using a hydrofluoric acid-based aqueous solution to remove the gate insulation film 32 except the gate insulation film 32 below the gate electrode 36 (FIG. 6C). In etching the gate insulation film 32 by dry etching, as shown in FIG. 9A, the surface of the silicon substrate 30 is often etched by some nanometers to tens nanometers.

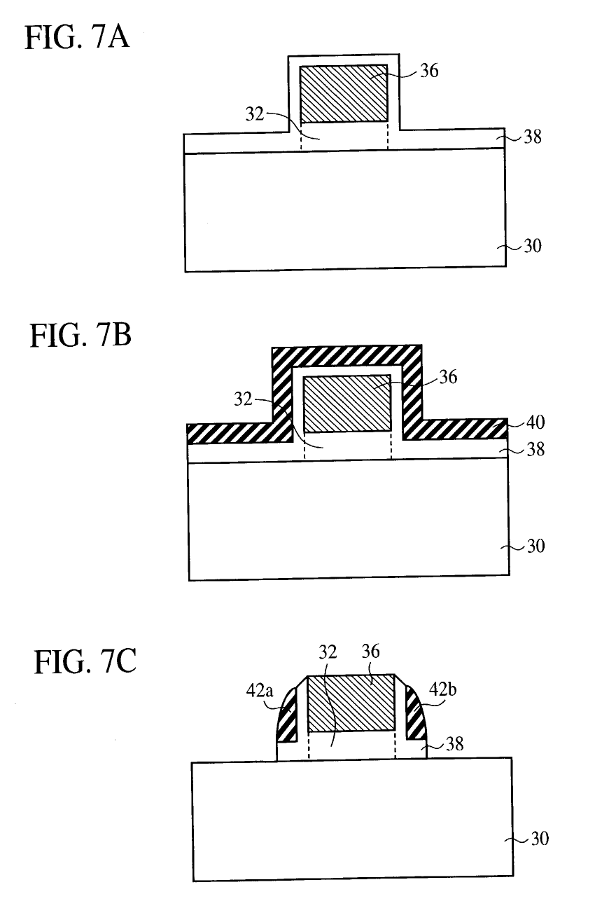

Next, the insulation film 38 of, e.g., 5 nm-thickness silicon oxide film is formed on the silicon substrate 30 and the gate electrode 36 by, e.g., thermal oxidation or CVD (FIG. 7A).

Next, a 20 nm-thickness silicon nitride film 40, for example, is deposited on the insulation film 38, by, e.g., CVD (FIG. 7B).

Then, the silicon nitride film 40 and the insulation film 38 are etched back by, e.g., reactive ion etching to form the sidewall charge accumulation layers 42a, 42b of the silicon nitride film 40 on the side walls of the gate electrode 36 with the insulation film 38 formed on (FIG. 7C).

Next, the insulation film 48 of, e.g., 50 nm-thickness silicon oxide film is deposited on the entire surface by, e.g., CVD.

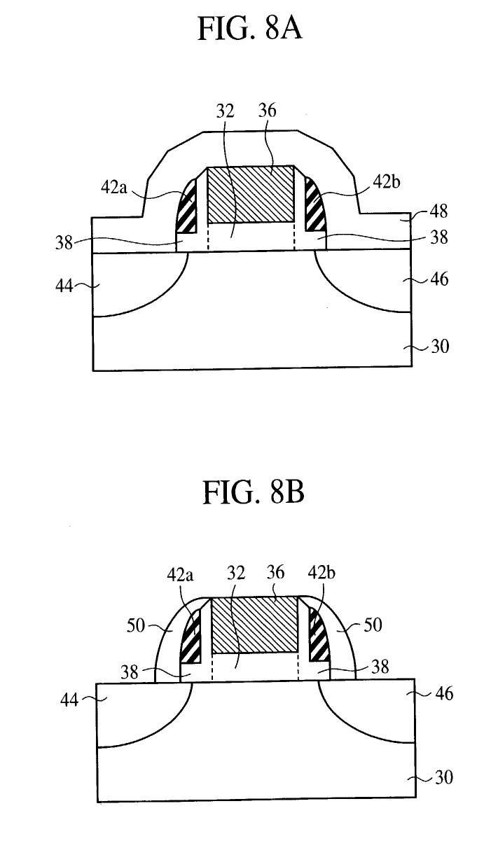

Next, with the gate electrode 36, the insulation film 38 and the sidewall charge accumulation layers 42a, 42b as a mask, arsenic ions, for example, are implanted to form the source region 44 and the drain region 46 in the silicon substrate 30 on both sides of the gate electrode 36. Thus, the ends of the junctions of the source region 44 and the drain region 46 on the side of the channel are positioned outside the gate electrode 36 (FIG. 8A).

Although not shown, for higher reliability, the surface of the silicon substrate 30 and the surfaces of the sidewall charge accumulation layers 42a, 42b may be oxidized before the insulation film 48 is deposited.

Then, the insulation film 48 is etched back by, e.g., reactive ion etching until the upper surface of the gate electrode 36 is exposed to form the sidewall insulation film 50 of the silicon oxide film 48 on the side walls of the gate electrode 36 with the silicon oxide film 38 and the sidewall charge accumulation layers 42a, 42b formed on (FIG. 8B). When the silicon substrate 30 is etched as shown in FIG. 9A in the step of FIG. 6C, a configuration after the sidewall insulation film 50 has been formed is as shown in FIG. 9B.

Thus, the memory cell structure of the non-volatile semiconductor memory device according to the present embodiment shown in FIG. 5 is completed.

As described above, according to the present embodiment, the sidewall charge accumulation layers are formed on the side walls of the gate electrode respectively on the side of the source region and the side of the drain region to thereby store required information. Accordingly, charges accumulated in the side of the source region and charges accumulated on the side of the drain region can be easily spatially isolated from each other. Thus, even with a very short gate length, the 2-bit operation can be ensured.

A thickness of the insulation film formed between the substrate and the sidewall charge accumulation layers is smaller than that of the insulation film between the substrate and the gate electrode, whereby characteristics of writing in the sidewall charge accumulation layers can be improved.

### A Second Embodiment

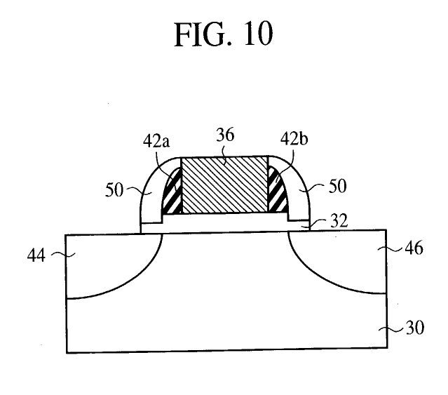

The semiconductor device according to a second embodiment of the present invention and the method for fabricating the semiconductor device will be explained with reference to FIGS. 10 to 12B. The same reference numbers of the present embodiment as those of the non-volatile semiconductor memory device according to the first embodiment and the method for fabricating the same shown in FIGS. 5 to 9B are represented by the same reference numbers not to repeat or to simplify their explanation.

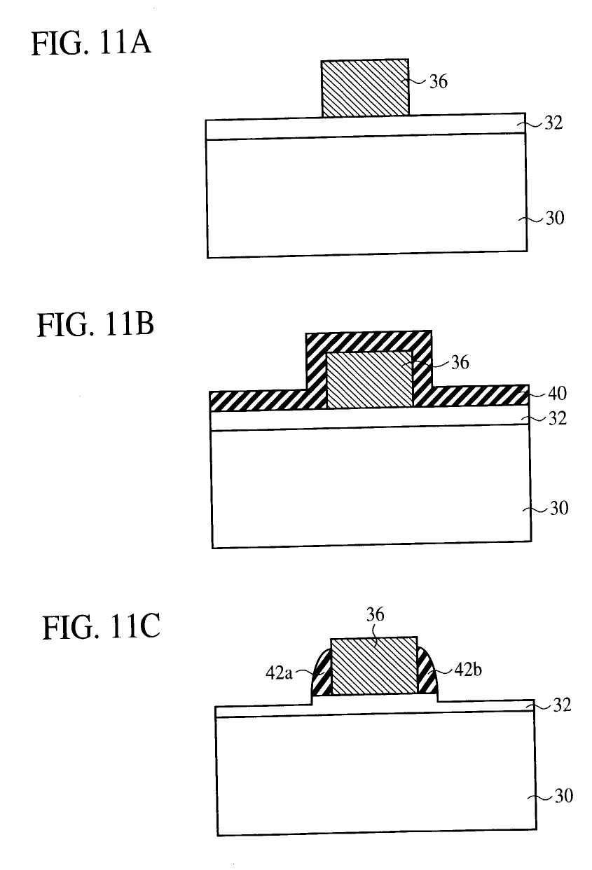

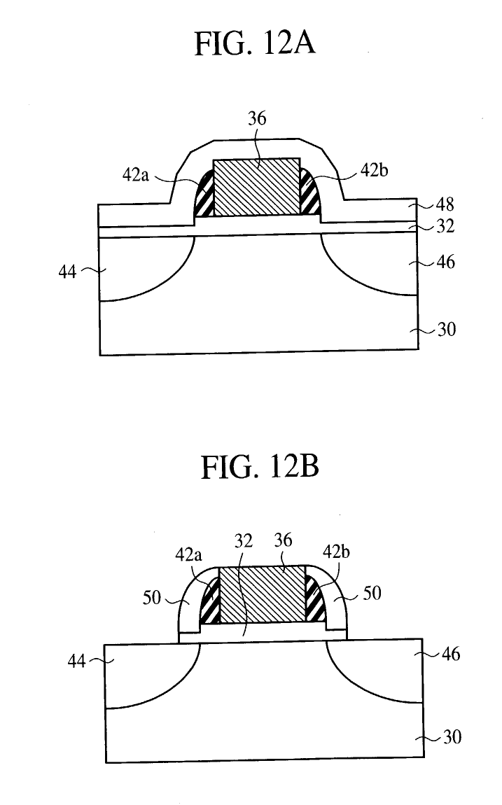

FIG. 10 is a diagrammatic sectional view of the non-volatile semiconductor memory device according to the present embodiment, which show a structure thereof. FIGS. 11A to 12B are sectional views of the non-volatile semiconductor memory device according to the present embodiment in the steps of the method for fabricating the same, which explain the method.

The basic structure of the non-volatile semiconductor memory device according to the present embodiment is the same as that of the non-volatile semiconductor memory device according to the first embodiment shown in FIG. 5. The non-volatile semiconductor memory device according to the present embodiment is characterized mainly in that a film thickness of an insulation film 32 between a silicon substrate 30 and a gate electrode 36 is substantially the same as that between sidewall charge accumulation layers 42 and the silicon substrate 30. Such constitution makes the present embodiment inferior to the non-volatile semiconductor memory device according to the first embodiment in the writing characteristics but is advantageous in making the fabrication steps simple.

Next, the method for fabricating the non-volatile semiconductor memory device according to the present embodiment will be explained with reference to FIGS. 11A to 12B.

First, the gate insulation film 32 and the gate electrode 36 are formed on the silicon substrate 30 in the same way as in, e.g., the method for fabricating the non-volatile semiconductor memory device according to the first embodiment shown in FIGS. 6A and 6B (FIG. 11A).

Then, a 20 nm-thickness silicon nitride film 40, for example, is deposited on the silicon substrate 30 and the gate electrode 36 by, e.g., CVD (FIG. 11B).

Next, the silicon nitride film 40 is etched back by, e.g., reactive ion etching to form the sidewall charge accumulation layers 42a, 42b of the silicon nitride film 40 on the side walls of the gate electrode 36 (FIG. 11C).

Then, with the gate electrode 36 and the sidewall charge accumulation layers 42a, 42b as a mask, arsenic ions, for example, are implanted to form the source region 44 and the drain region 46 in the silicon substrate 30. Thus, the ends of the junctions of the source region 44 and the drain region 46 on the side of the channel are positioned outer of the gate electrode 36.

Next, the insulation film 48 of, e.g., 50 nm-thickness silicon oxide film is deposited on the entire surface by, e.g., CVD (FIG. 12A).

Then, the insulation film 48 is etched back to expose the upper surface of the gate electrode 36 by, e.g., reactive ion etching to form the sidewall insulation film 50 of the insulation film 48 on the sidewalls of the gate electrode 36 with the sidewall charge accumulation layers 42a, 42b.

Thus, the memory cell structure of the non-volatile semiconductor memory device according to the present embodiment shown in FIG. 10 is completed.

As described above, according to the present embodiment, the sidewall charge accumulation layers are formed on the side walls of the gate electrode respectively on the side of the source region and the drain region so as to accumulate charges in the sidewall charge accumulation layers to store required information. Accordingly, charges accumulated on the side of the source region and charges accumulated on the side of the drain can be easily spatially isolated from each other. Thus, even with a very short gate length, the 2-bit operation can be ensured.

A thickness of the insulation film between the substrate and the gate electrode is substantially the same as that between the substrate and the sidewall charge accumulation layers, whereby the fabrication steps can be simple in comparison with the non-volatile semiconductor memory device according to the first embodiment.

### A Third Embodiment

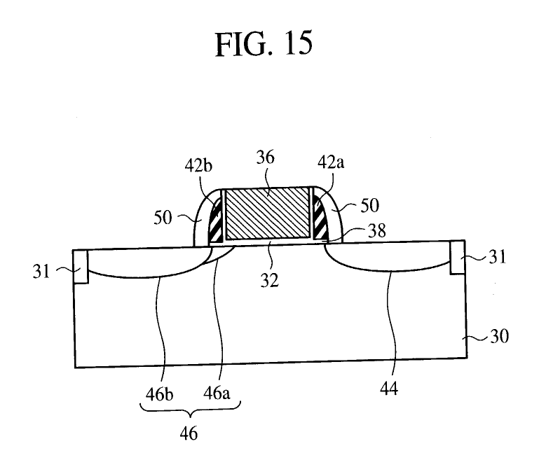

The non-volatile semiconductor memory device according to a third embodiment of the present invention and the method for fabricating the non-volatile semiconductor memory device will be explained with reference to FIGS. 15 to 27B. FIG. 15 is a sectional view of the non-volatile semiconductor memory device according to the present embodiment. The same members of the present embodiment as those of the non-volatile semiconductor memory device according to the first or the second embodiment and the method for fabricating the same are represented by the same reference numbers not to repeat or to simplify their explanation.

(The Non-Volatile Semiconductor Memory Device)

The non-volatile semiconductor memory device according to the present embodiment is characterized mainly in that the end of the junction of a source region 44 on the side of a gate electrode 36 is spaced from the region of a semiconductor substrate 30 immediately below the gate electrode 36, and the end of the junction of a drain region 46 on the side of the gate electrode 36 is positioned immediately below the gate electrode 36.

As shown in FIG. 15, the source region 44 and the drain region 46 are formed in an element region defined by an element isolation region 31.

The drain region 46 has an LDD (Lightly Doped Drain) structure including a lightly doped drain region 46a and a heavily doped drain region 46b. The end part of the heavily doped region 46b on the side of the gate electrode 36 is not extended up to a part immediately below the gate electrode 36 but to a part between the region below a charge accumulation layer 42b and the region below a sidewall insulation film 50. The edge of the lightly doped drain region 46a on the side of the gate electrode 36 is positioned immediately below the gate electrode 36. Accordingly, the end of the junction of the drain region 46 formed of the lightly doped drain region 46a and the heavily doped drain region 46b is positioned immediately below the gate electrode 36.

On the other hand, the source region 44 does not have the LDD structure but has only a heavily doped source region. The end of the junction of the source region 44 on the side of the gate electrode 36 is not extended up to a region below the gate electrode 36 but is positioned in a region below the sidewall charge accumulation layer 42a to a region below the sidewall insulation film 50.

The non-volatile semiconductor memory device according to the present embodiment is thus constituted.

In the non-volatile semiconductor memory device according to the first or the second embodiment, in which the ends of the junctions of the source region 44 on the side of the gate electrode 36 and the end of the junction of the drain region 46 on the side of the gate electrode 36 are both spaced from the region of the semiconductor substrate 30 immediately below the gate electrode 36, the distance between the source region 44 and the drain region 46, i.e., the channel length, is longer in comparison with that of the general MOS transistor. Accordingly, the non-volatile semiconductor memory device according to the first and the second embodiments often has low operational speed.

In contrast to this, in the present embodiment, only the end of the junction of the source region 44 on the side of the gate electrode 36 is spaced from the region of the semiconductor substrate 30 immediately below the gate electrode 38, and the end of the junction of the drain region 46 on the side of the gate electrode 36 is positioned immediately below the gate electrode 36. Accordingly, the present embodiment can have a shorter channel length in comparison with the first and the second embodiments, and can provide a non-volatile semiconductor memory device whose operation speed is high. The non-volatile semiconductor memory device according to the present embodiment, in which the end of the junction of the drain region 46 on the side of the gate electrode 36 is positioned immediately below the gate electrode 36, cannot operate as a memory of 2-bit operation but can operate as a memory of 1-bit operation.

When charges are accumulated in the sidewall charge accumulation layer 42a, i.e., information is written, a higher voltage is applied to the gate electrode 36 than to the source region 44.

When the absence/presence of charges accumulated in the sidewall charge accumulation layer 42a, i.e., information is read, a bias is applied forward. That is, the forward application of a bias means that charges are accumulated in the sidewall charge accumulation layer 42a, and a higher voltage is applied to the drain region 46 than to the source region 44.

When a charge accumulated in the sidewall charge accumulation layer is discharged, i.e., information is erased, a higher voltage is applied to the source region 44 than to the gate electrode 36.

When a charge is accumulated in the sidewall charge accumulation layer 42a, an about 1.5 V threshold voltage shift can be obtained (see FIG. 14) in comparison with the case that no charge is accumulated in the sidewall charge accumulation layer 42a, and the absence/presence of accumulated charges can be confirmed, based on drain current changes which are based on a threshold voltage of the transistor.

(The Method for Fabricating the Non-Volatile Semiconductor Memory Device)

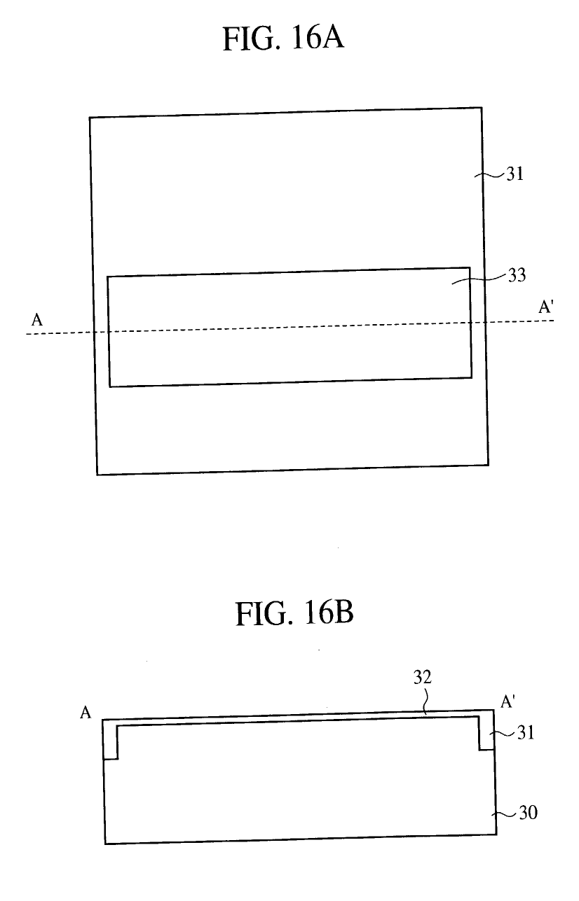

Then, the method for fabricating the non-volatile semiconductor memory device according to the present embodiment will be explained with reference to FIGS. 16A to 27B. FIGS. 16A to 27B are sectional views of the semiconductor device according to the present embodiment, which show the method. In FIGS. 16A to 27B, “A” indicates plan views, and “B” indicate sectional views along the line A-A′.

First, as shown in FIGS. 16A and 16B, an element isolation region 31 for defining an element region 33 is formed by, e.g., STI.

The following steps from the step of forming a gate insulation film 32 to the step of forming an insulation film 48 including the insulation film 48 forming step (see FIGS. 16A to 23B) are the same as those of the method for fabricating the non-volatile semiconductor memory device shown in FIGS. 6A to 8A.

That is, the surface of a p type silicon substrate 30 is oxidized by, e.g., thermal oxidation to form the gate insulation film 32 of a silicon oxide film of, e.g., a 8 nm-film thickness.

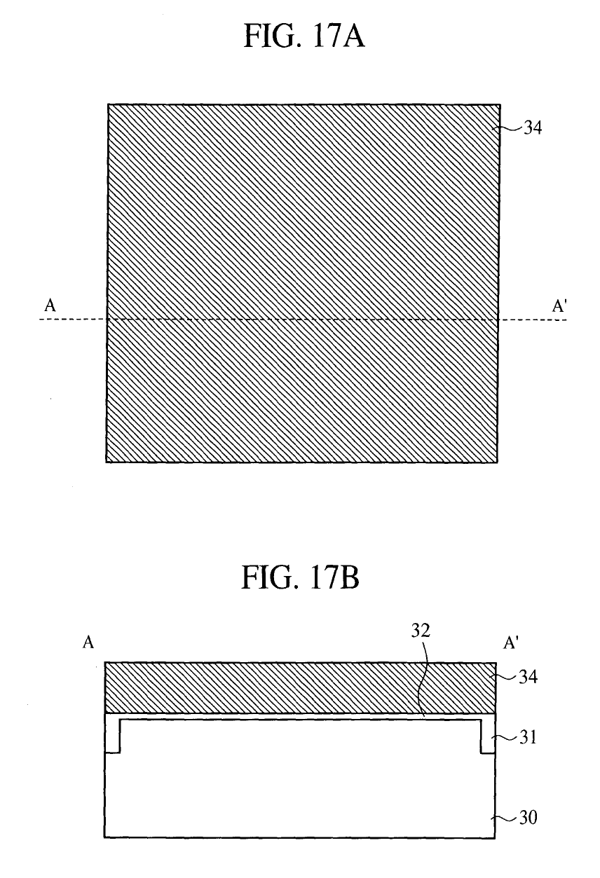

Then, as shown in FIGS. 17A and 17B, an n⁺ type polycrystal silicon film 34 of, e.g., a 180 nm-thickness is formed on the gate insulation film 32.

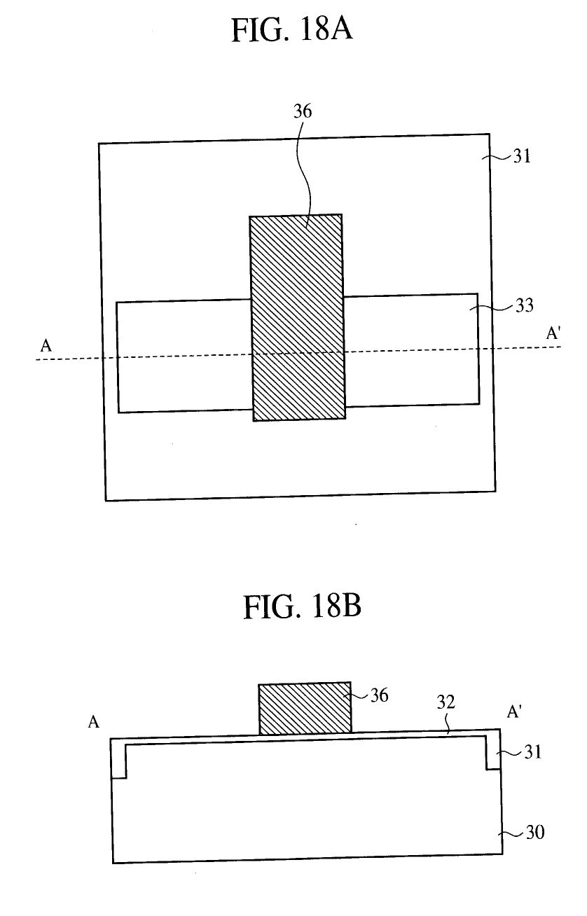

Next, as shown in FIGS. 18A and 18B, the polycrystal silicon film is patterned by lithography and dry etching to form a gate electrode 36 of the polycrystal silicon film.

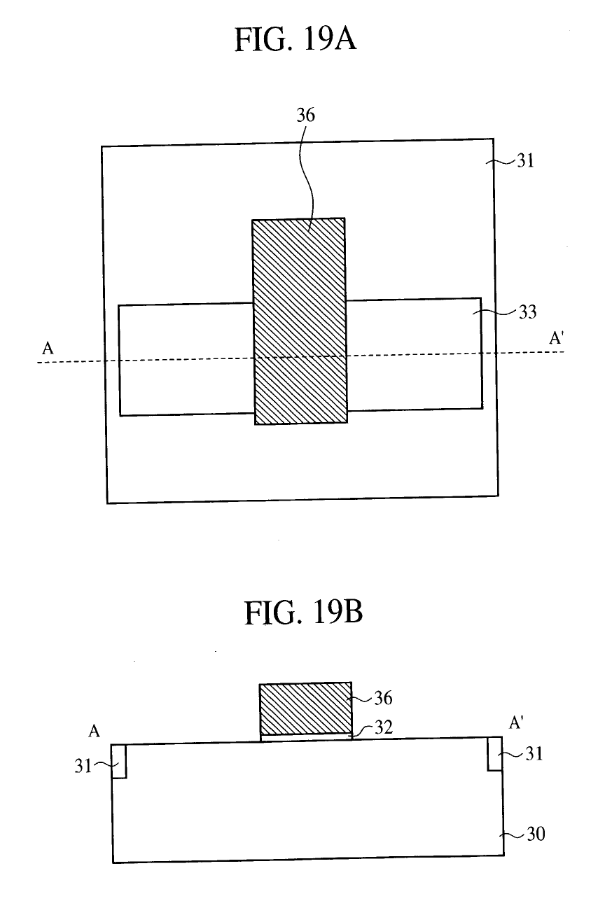

Then, as shown in FIGS. 19A and 19B, the gate insulation film 32 is etched by dry etching or wet etching using a hydrofluoric acid-based aqueous solution to remove the gate insulation film 32 in the region other than the region below the gate electrode 36.

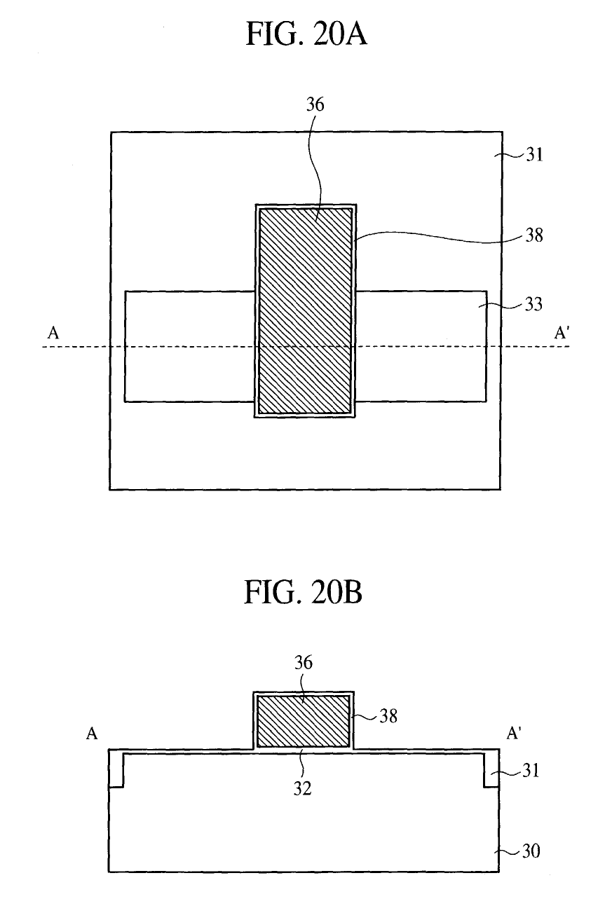

Next, as shown in FIGS. 20A and 20B, an insulation film 38 of a silicon oxide film of, e.g., a 5 nm-film thickness is formed on the silicon substrate 30 and the gate electrode 36 by, e.g., thermal oxidation or CVD.

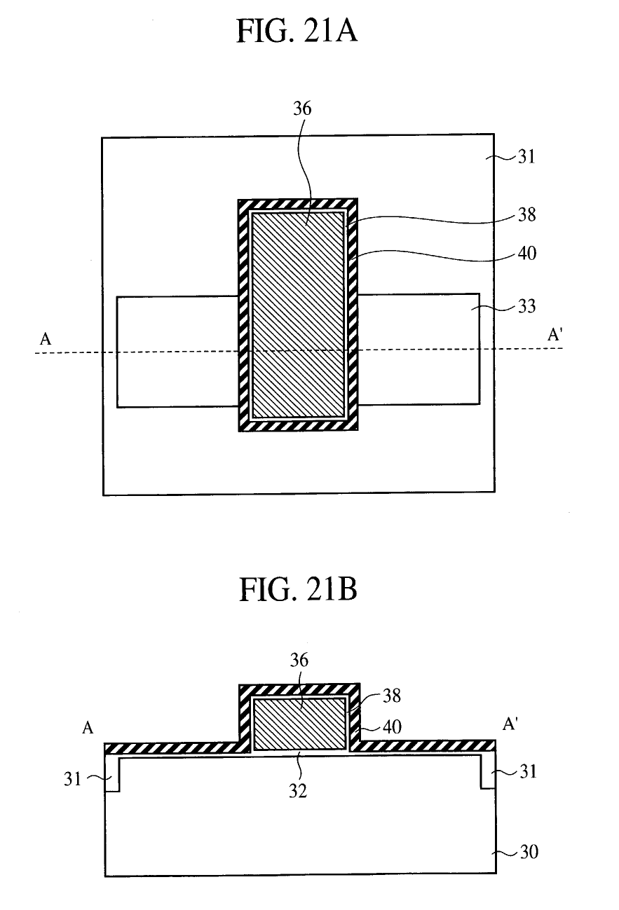

Next, as shown in FIGS. 21A and 21B, a silicon nitride film 40 of, e.g., a 20 nm-film thickness is deposited on the insulation film 38 by, e.g., CVD.

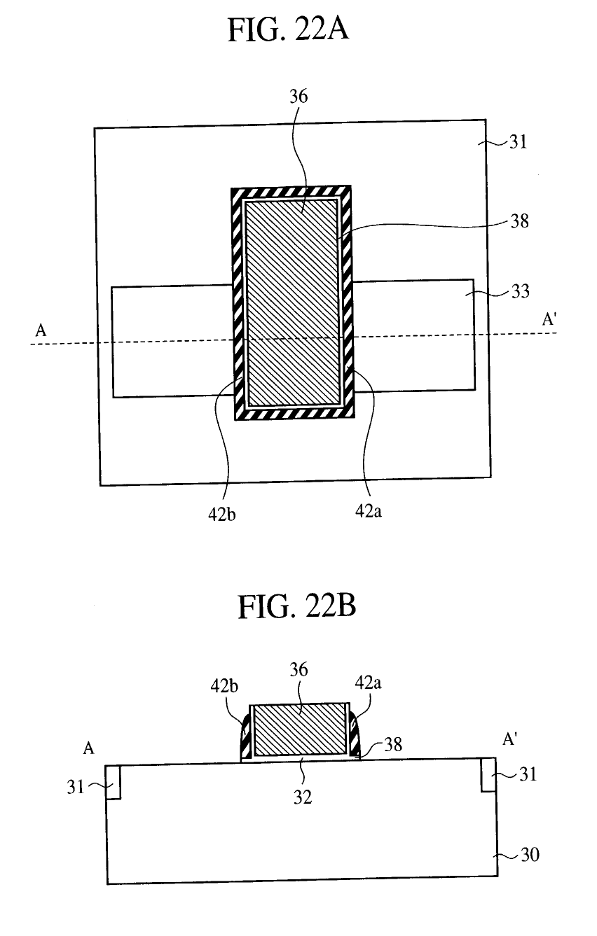

Then, as shown in FIGS. 22A and 22B, the silicon nitride film 40 and the insulation film 38 are etched back by, e.g., reactive ion etching to form the sidewall charge accumulation layers 42a, 42b of the silicon nitride film 40 on the side wall of the gate electrode 36 with the insulation film 38 formed on.

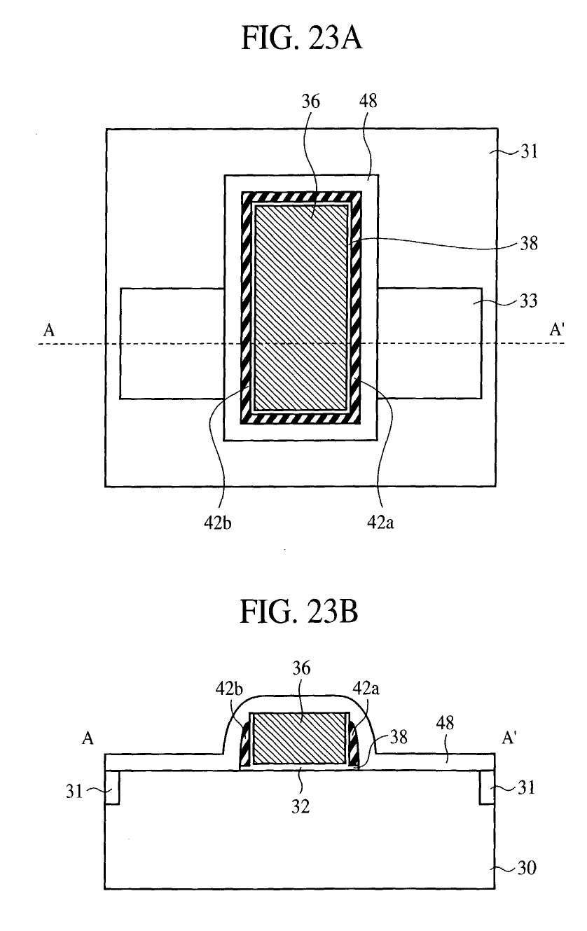

Then, as shown in FIGS. 23A and 23B, an insulation film 48 of a silicon oxide film, e.g., a 50 nm-film thickness is formed on the entire surface by, e.g., CVD.

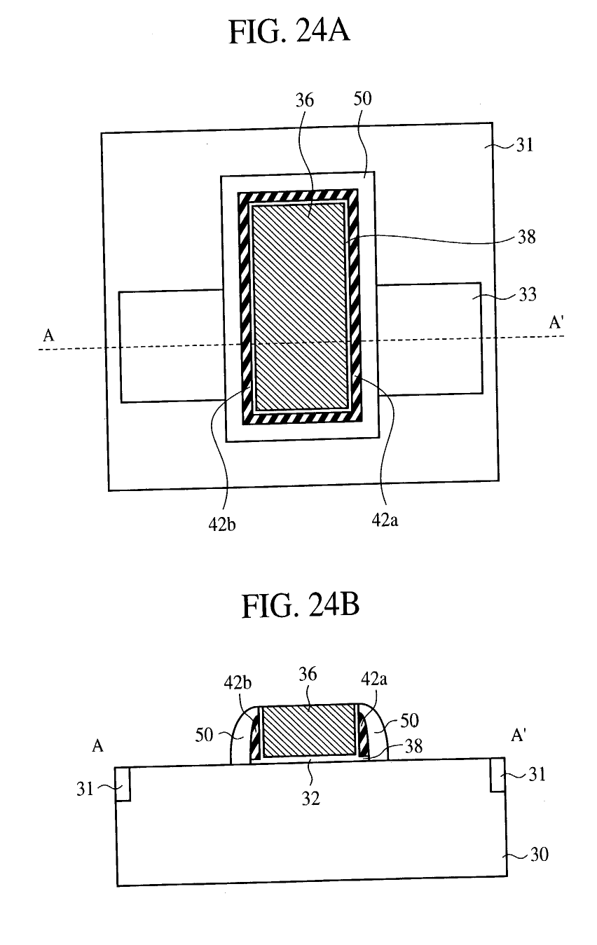

Next, as shown in FIGS. 24A and 24B, the insulation film 48 is etched back by, e.g., reactive ion etching until the upper surface of the gate electrode 36 is exposed to thereby form a sidewall insulation film 50 of the silicon oxide film 48 on the side wall of the gate electrode 36 with the silicon oxide film 38 and the sidewall charge accumulation layers 42a. 42b formed on.

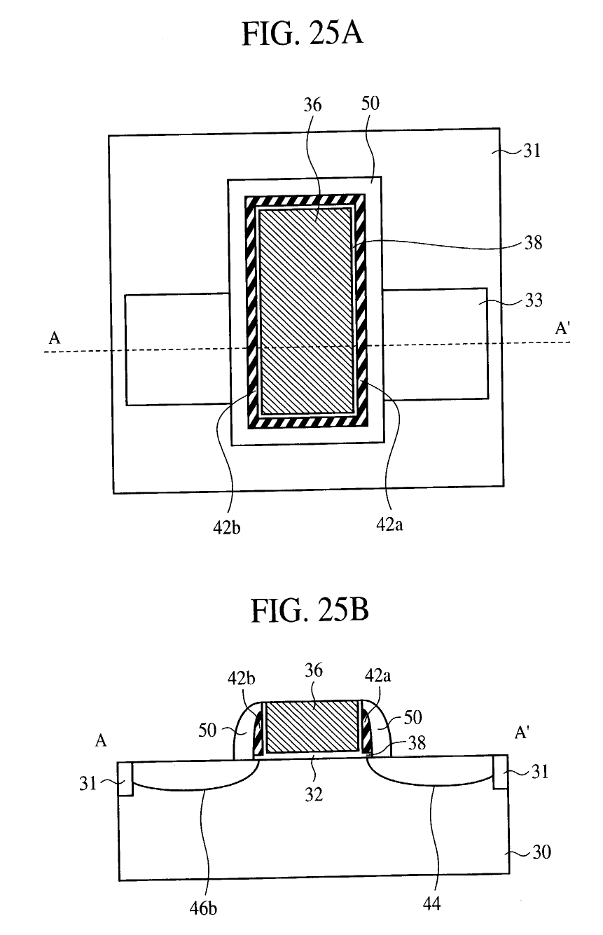

Next, as shown in FIGS. 25A and 25B, with the gate electrode 36, the insulation films 38, 48, the sidewall charge accumulation layers 42a, 42b and the sidewall insulation film 50 as a mask, arsenic ions, for examples are implanted. Thus, the source region 44 and the heavily doped drain region 46b are formed in the silicon substrate 30 on both sides of the gate electrodes 36. The ends of the source region 44 and the heavily doped region 46b on the side of the channel are positioned outer of the gate electrode 36.

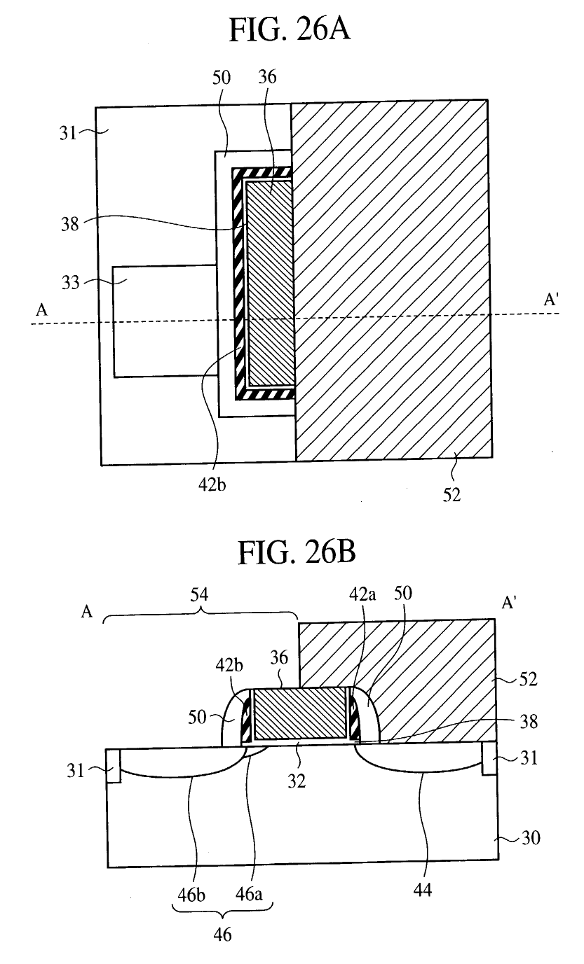

Then, as shown in FIGS. 26A and 26B, a photoresist film 52 is formed by, e.g., spin coating.

Then, an opening 54 is opened in the photoresist film 52 for opening a region where the drain region is to be formed.

The, with the photoresist film 52 as a mask, arsenic ions, for example, are implanted diagonally with respect to the substrate surface. Thus, the lightly doped drain region 46a is formed. The lightly doped drain region 46a and the heavily doped drain region 46b form the drain region 46 of the LDD structure.

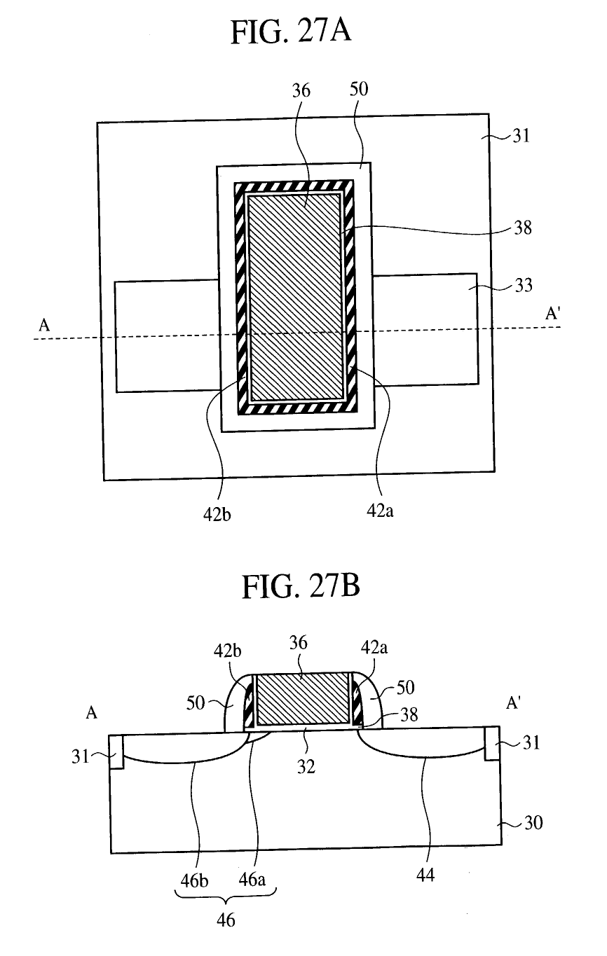

Thus, the memory cell structure of the non-volatile semiconductor memory device according to the present embodiment is completed (see FIGS. 27A and 27B).

(A Modification)

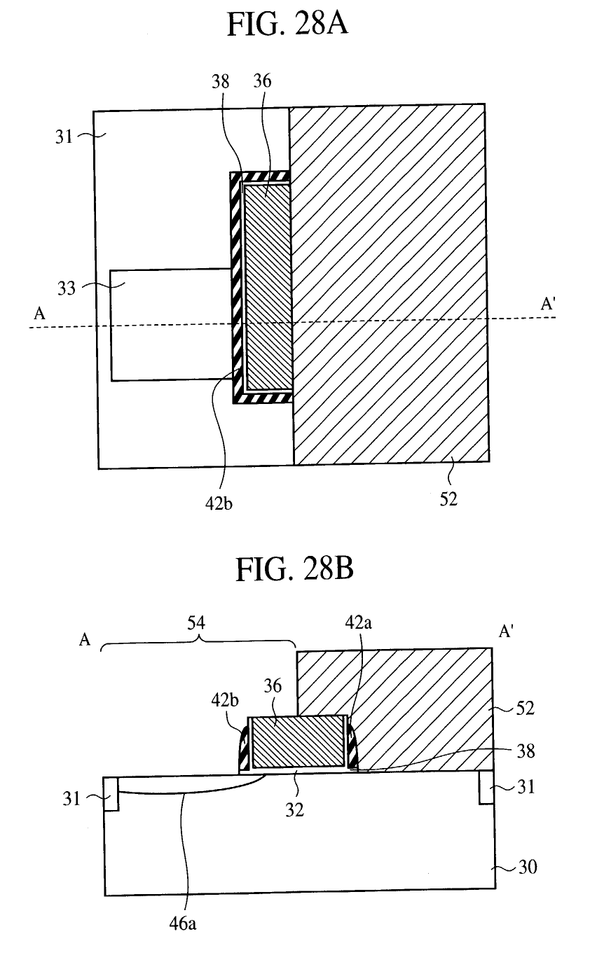

Then, a modification of the method for fabricating the non-volatile semiconductor memory device according to the present embodiment will be explained with reference to FIGS. 28A to 31B. FIGS. 28A to 31B are sectional views of the non-volatile semiconductor memory device according to the present modification in the steps of the method for fabricating the same, which show the method. In FIGS. 28A to 31B, “A” indicates plan views, and “B” indicates sectional views along the line A-A′.

The method for fabricating the non-volatile semiconductor memory device according to the present modification is characterized mainly in that the lightly doped drain region 46a is formed before the step of forming the heavily doped drain region 46b.

The steps up to the step of forming the sidewall charge accumulation layers 42a, 42b of the silicon nitride film 40 on the side wall of the gate electrode 36 with the insulation film 38 formed on including the sidewall charge accumulation layer forming step are the same as those of the method for fabricating the semiconductor device shown in FIGS. 16A to 22B, and their explanation will be omitted.

Next, as shown in FIGS. 28A and 28B, a photoresist film 52 is formed by, e.g., spin coating.

Then, an opening 54 for opening the region where the drain region 46 is to be formed is formed in the photoresist film 52.

Next, with the photoresist film 52 as a mask, arsenic ions, for example, are implanted diagonally with respect to the substrate surface. Thus, the lightly doped drain region 46a is formed.

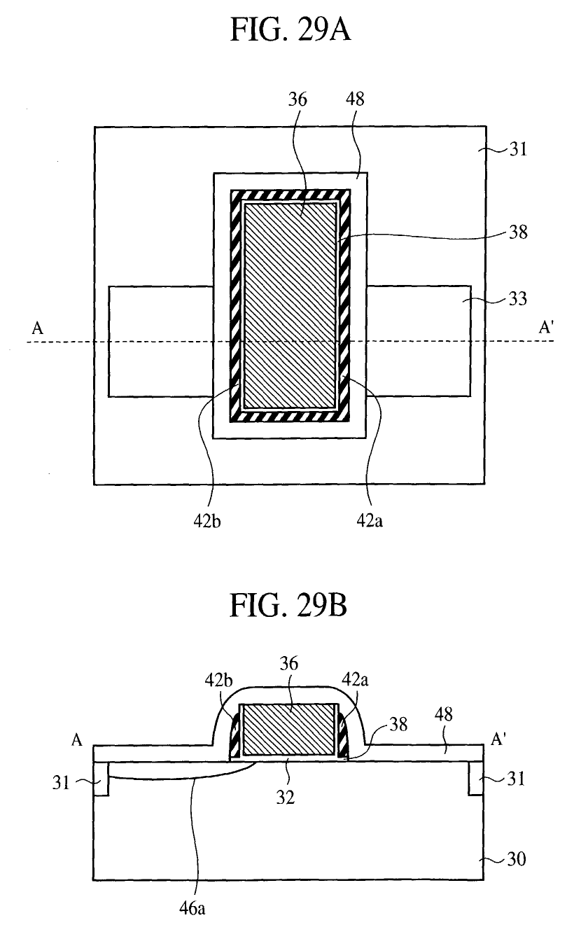

Then, as shown in FIGS. 23A and 23B, in the same way as in the method for fabricating the non-volatile semiconductor memory device shown in FIGS. 23A and 23B, an insulation film 48 of a silicon oxide film of, e.g., a 50 nm-thickness is deposited (see FIGS. 29A and 29B).

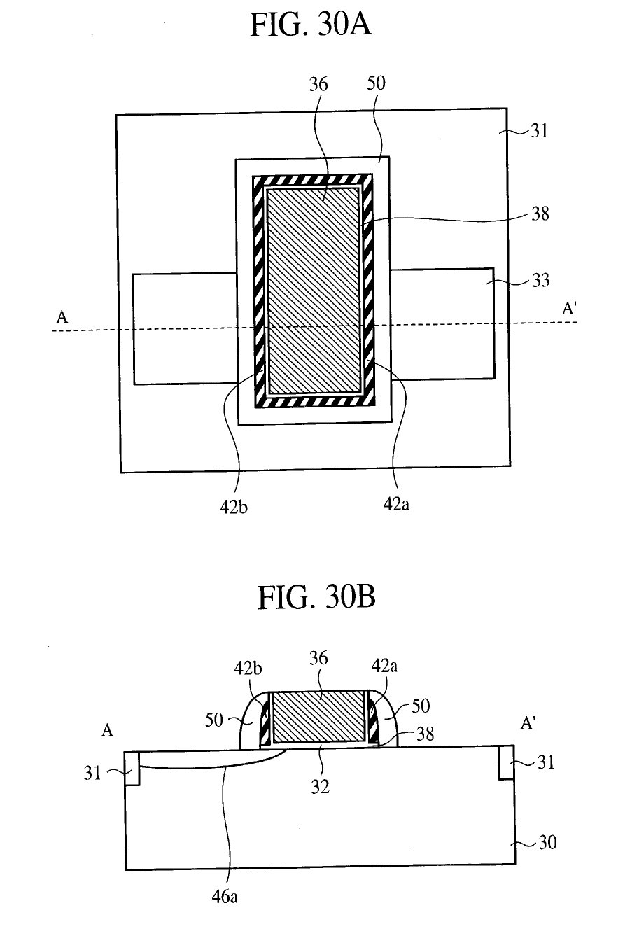

Then, in the same way as in the method for fabricating the non-volatile semiconductor memory device shown in FIGS. 24A and 24B, the insulation film 48 is etched back until the upper surface of the gate electrode 36 is exposed to form the sidewall insulation film 50 of the silicon oxide film 48 on the side wall of the gate electrode 36 with the silicon oxide film 38 and the sidewall charge accumulation layers 42a, 42b formed on (see FIGS. 30A and 30B).

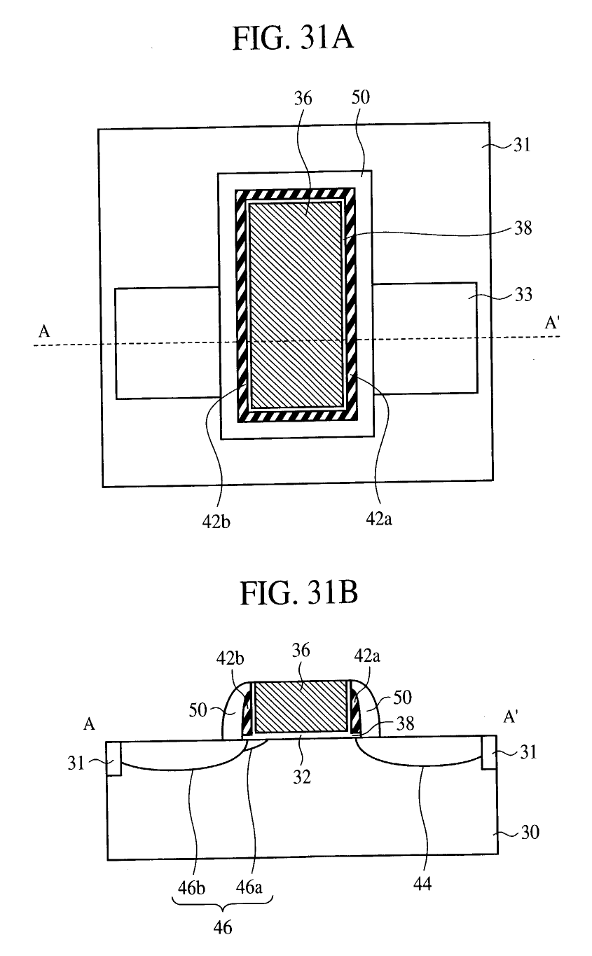

Next, in the same way as in the method for fabricating the non-volatile semiconductor memory device shown in FIGS. 25A and 25B, with the gate electrode 36, the insulation films 38, 48, the sidewall charge accumulation layers 42a, 42b and the sidewall insulation film 50 as a mask, arsenic ions, for example, are implanted. Thus, the source region 44 and the heavily doped region 46b are formed. The end of the source region 44 on the side of the channel is positioned outer of the gate electrode 36. Thus, the source region 44, and the drain region 46 of the LDD structure are formed (see FIGS. 31A and 31B).

Thus, the memory cell structure of the non-volatile semiconductor memory device according to the present modification can be completed.

Thus, the lightly doped drain region 46a may be formed before the step of forming the heavily doped drain region 46b.

### A Fourth Embodiment

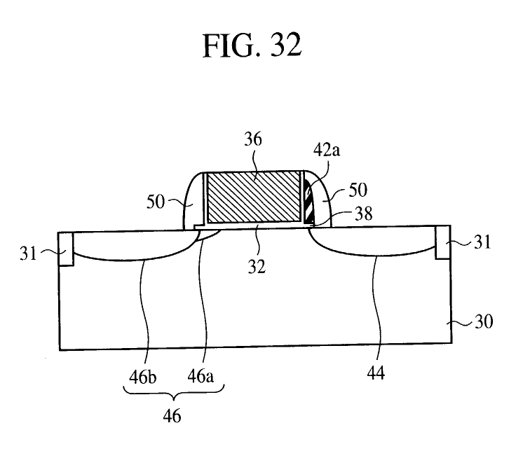

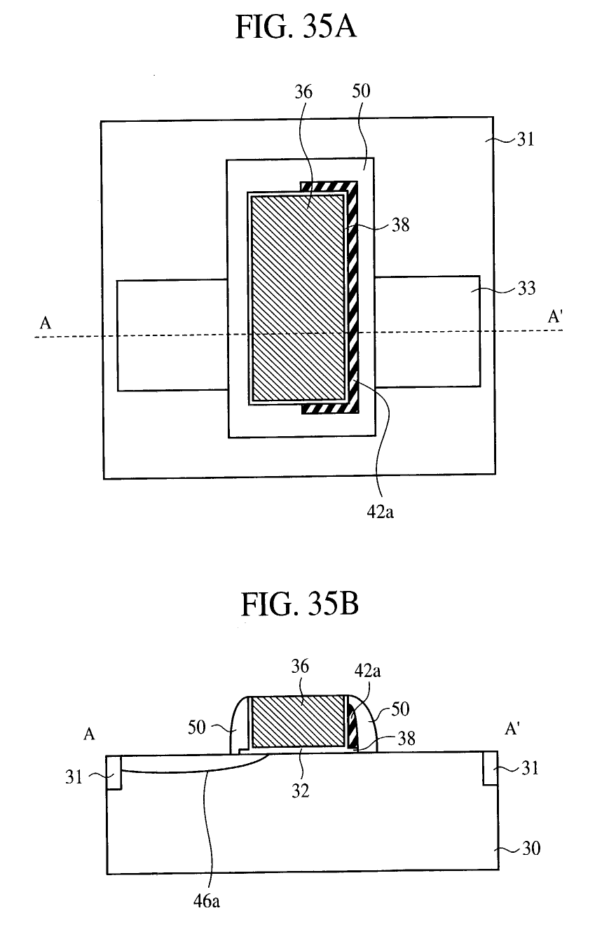

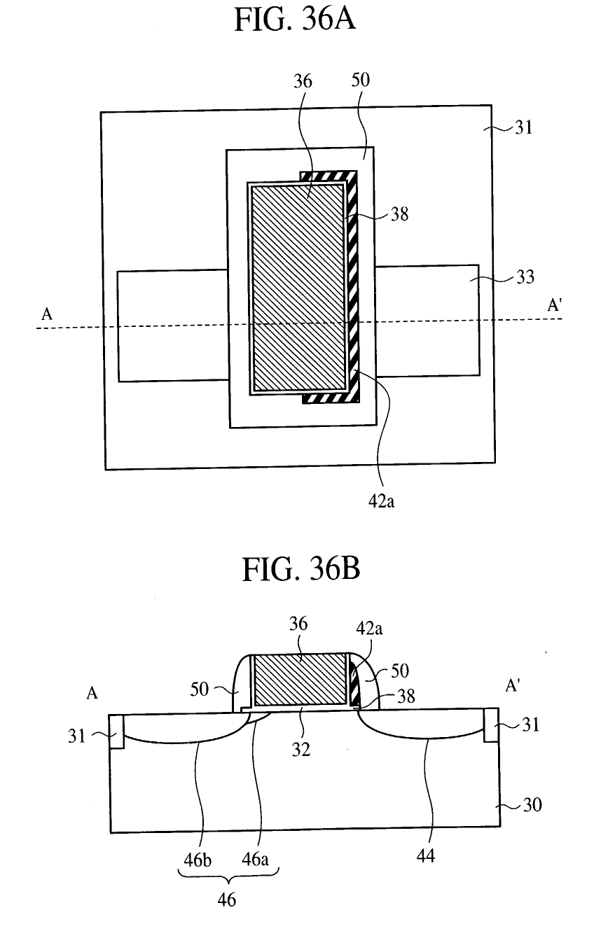

The non-volatile semiconductor memory device according to a fourth embodiment of the present invention and the method for fabricating the same will be explained with reference to FIGS. 32 to 36B. FIG. 32 is a sectional view of the non-volatile semiconductor memory device according to the present embodiment. The same member of the present embodiment as those of the non-volatile semiconductor device according to the first to the third embodiments are represented by the same reference numbers not to repeat or to simplify their explanation.

(The Non-Volatile Semiconductor Memory Device)

The non-volatile semiconductor memory device according to the present embodiment is characterized mainly in that the sidewall charge accumulation layer 42a is formed only on the side wall of the gate electrode 36 on the side of the source region 44, and the sidewall charge accumulation layer is not formed on the side wall of the gate electrode 36 on the side of the drain region 46.

As shown in FIG. 32, a sidewall charge accumulation layer 42a of a silicon nitride film is formed on the side wall of the gate electrode 36 on the side of source region 44. On the other hand, the sidewall charge accumulation layer is not formed on the side wall of the gate electrode 36 on the side of the drain region 46.

A sidewall insulation film 50 is formed on the sidewall part of the gate electrode 36 where the sidewall charge accumulation layer 42a is formed.

As in the non-volatile semiconductor memory device according to the third embodiment, the drain region has the LDD structure having the light doped drain region 46a and the heavily doped drain region 46b. As in the non-volatile semiconductor memory device according to the third embodiment, the end of the junction of the drain region 46 on the side of the gate electrode 36 is extended into the region below the gate electrode 36.

On the other hand, the source region 44 is formed of a heavily doped source region alone, as in the non-volatile semiconductor memory device according to the third embodiment. The end of the junction of the source region 44 on the side of the gate electrode 44 is not extended into the region below the gate electrode 36 but is positioned in between the region below the sidewall charge accumulation layer 42a and the region below the sidewall insulation film 50.

The non-volatile semiconductor memory device according to the present embodiment is thus constituted.

As described above, the non-volatile semiconductor memory device according to the present embodiment is characterized mainly in that the sidewall charge accumulation layer 42a is formed only on the side wall of the gate electrode 36 on the side of the source region 44, and the sidewall charge accumulation layer is not formed on the part of the sidewall of the gate electrode 36 on the side of the drain region 46.

For the memory cell to function as a 1-bit operation memory cell, the sidewall charge accumulation layer 42a may be formed only on the side wall of the gate electrode 36 on the side of the source region 44. Accordingly, the non-volatile semiconductor memory device according to the present embodiment as well as the non-volatile semiconductor memory device according to the third embodiment can function as a 1-bit operation memory cell.

(The Method for Fabricating the Non-Volatile Semiconductor Memory Device)

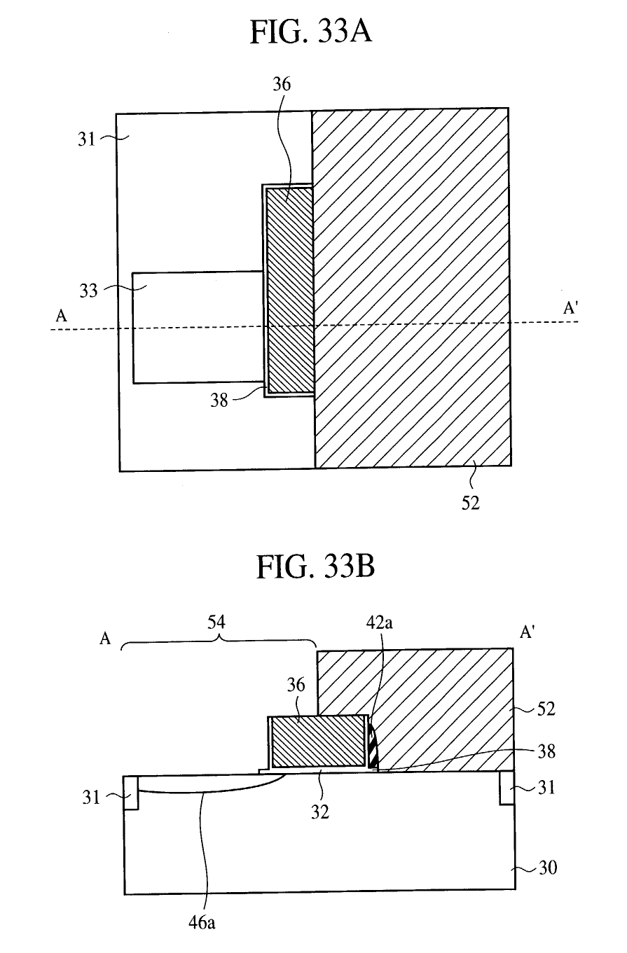

Next, the method for fabricating the non-volatile semiconductor memory device according to the present embodiment will be explained with reference to FIGS. 33A to 36B. FIGS. 33A to 36B are sectional views of the non-volatile semiconductor memory device according to the present embodiment in the steps of the method for fabricating the same, which explain the method. In FIGS. 33A to 36B, “A” indicates plan views, and “B” indicates sectional views along the line A-A′.

First, the steps to the step of forming the sidewall charge accumulation layers 42a, 42b of the silicon nitride film 40 on the side wall of the gate electrode 36 with the insulation film 38 formed on including the sidewall charge accumulation layers 42a, 42b forming step are the same as in the method for fabricating the non-volatile semiconductor memory device shown in FIGS. 16A to 22B, and their explanation will be omitted.

Then, as shown in FIGS. 33A and 33B, a photoresist film 52 is formed by, e.g., spin coating.

Then, an opening 54 for opening the region where a drain region 46 to be formed is formed in the photoresist film 52.

Next, with the photoresist film 52 as a mask, the sidewall charge accumulation layer 42b is etched off. Thus, the sidewall charge accumulation layer 42b formed on the side wall of the gate electrode 36 on the side of the drain region 46 is removed (see FIGS. 22A and 22B).

Next, with the photoresist film 52 and the gate electrode 36 as a mask, arsenic ions, for example, are implanted diagonally with respect to the substrate surface. Thus, a lightly doped drain region 46a is formed. The end of the lightly doped drain region 46a on the side of the gate electrode 36 is positioned in the region below the gate electrode 36.

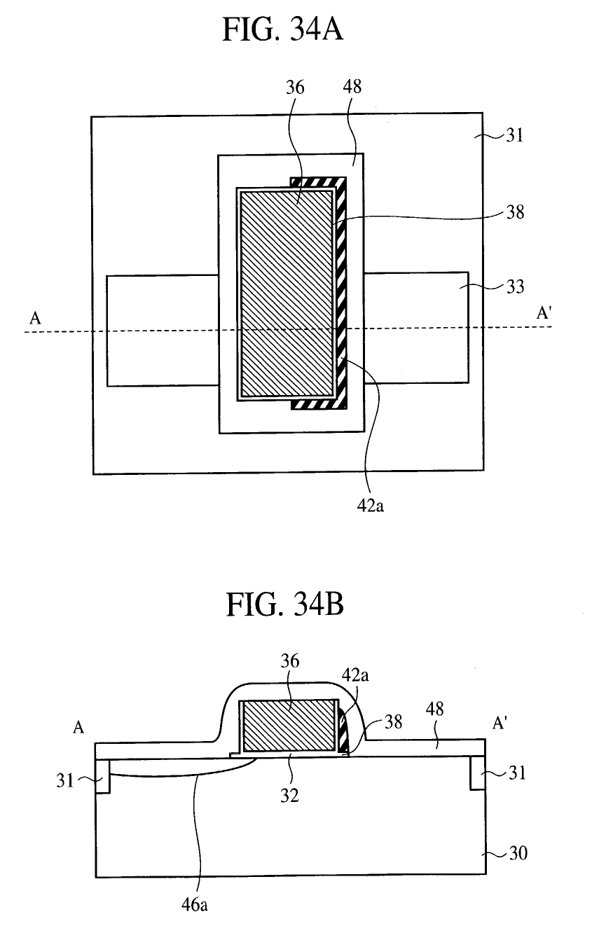

The following steps of the method for fabricating the non-volatile semiconductor memory device according to the present embodiment are the same as those of the method for fabricating the non-volatile semiconductor memory device shown in FIGS. 29A to 31B, and their explanation will be omitted (see FIGS. 34A to 36B).

Thus, the memory cell structure of the non-volatile semiconductor memory device according to the present modification is completed.

### A Fifth Embodiment

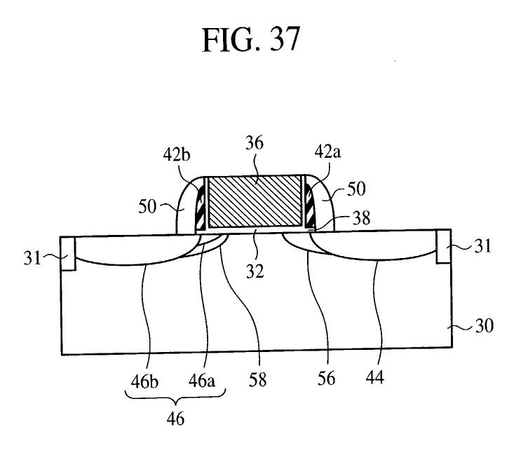

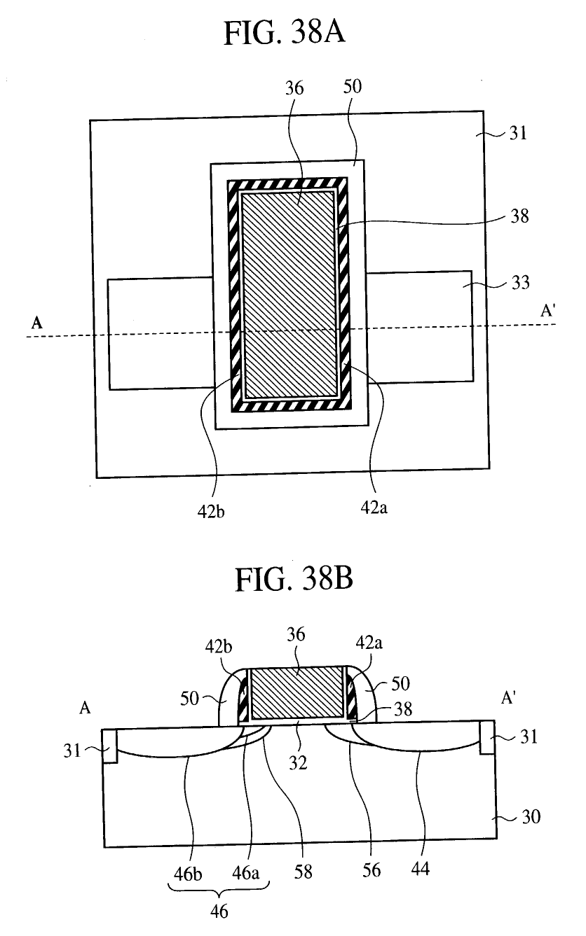

The non-volatile semiconductor memory device according to a fifth embodiment of the present invention and the method for fabricating the same will be explained with reference to FIGS. 37 to 38B. FIG. 37 is a sectional view of the non-volatile semiconductor memory device 3 according to the present embodiment. The same members of the present embodiment as those of the non-volatile semiconductor memory device according to the first to the fourth embodiments shown in FIGS. 5 to 36B are represented by the same reference numbers not to repeat or to simplify their explanation.

(The Non-Volatile Semiconductor Memory Device)

The non-volatile semiconductor memory device according to the present embodiment is characterized mainly in that doped regions 56, 58 having an conduction type oppose to that of a source region 44 and a drain region 46 are formed adjacent to the source region 44 and the drain region 46.

As shown in FIG. 37, the doped region 56 is formed adjacent to the source region 44 on the side of the channel. The doped region 58 is formed adjacent to the drain region on the side of the channel. A conduction type of the doped regions 56, 58 are opposite to that of the source region 44 and the drain region 46. When a conduction type of the semiconductor substrate 30 is p type, and a conduction type of the source region 44 and the drain region 46 is n type, a conduction type of the doped regions 56, 58 are p type. The dopant concentration of the doped regions 56, 58 are set higher than that of the semiconductor substrate 30.

In the present embodiment, in which the doped regions 56, 58 of a conduction type opposite to that of the source region 44 and the drain region 46 are formed adjacent to the source region 44 and the drain region 46, the ends of the junctions are positioned at the border between the source region 44 and the doped region 56 and at the border between the drain region 46 and the doped region 58. Steep dopant concentration profiles can be obtained between the end of the junction of the source region 44 on the side of the gate electrode 36 and the end of the junction of the drain region 46 on the side of the gate electrode 36. Accordingly, the non-volatile semiconductor memory device according to the present embodiment can be operative further without failure. The doped regions 56, 58 can function as pocket regions, which prevents the short channel effect.

As described above, the doped regions 56, 58 of a conduction type opposite to that of the source region 44 and the drain region 46 may be formed adjacent to the source region 44 and the drain region 46.

(The Method for Fabricating the Non-Volatile Semiconductor Memory Device)

Next, the method for fabricating the non-volatile semiconductor memory device according to the present embodiment will be explained with reference to FIGS. 38A and 38B. FIGS. 38A and 38B are sectional views of the non-volatile semiconductor memory device according to the present embodiment in the steps of the method for fabricating the same, which show the method. FIG. 38A is a plan view, and FIG. 38B is the sectional view along the line A-A′.

First, the steps to the step of forming the source region 44 and the drain region 46 are the same as those of the method for fabricating the non-volatile semiconductor memory device shown in FIGS. 16A to 27B, and their explanation will be omitted.

Then, boron ions, for example, are implanted diagonally with respect to the substrate surface. Thus, the doped regions 56, 58 of an opposite conduction type are formed. Boron tends to be more diffused than arsenic. Accordingly, the doped regions 56, 58 are formed, extended from the ends of the source region 44 and the drain region 46 on the side of the gate electrode 36 to the side of the channel (see FIGS. 38A and 38B).

Thus, the memory cell structure of the non-volatile semiconductor memory device according to the present embodiment is completed.

[Modifications]

The present invention is not limited to the above-described embodiments and can cover other various modifications.

For example, in the above-described embodiments, the sidewall charge accumulation layers are formed of silicon nitride film but may be formed of a dielectric film in place of silicon nitride film as long as the dielectric film can accumulate charges. For example, a layer film containing a silicon nitride film, a film (nanocrystal) of a structure containing conductor microcrystals in an insulator, or others can be used. Films of high dielectric constants, such as tantalum oxide, alumina, hafnium oxide, etc. may be used. These films can increase the field strength than silicon nitride film, and the writing characteristics can be improved.

In the first embodiment, a film thickness of the insulation film between the sidewall charge accumulation layer and the semiconductor substrate is smaller than that between the gate electrode and the semiconductor substrate, and in the second embodiment, a film thickness of the insulation film between the sidewall charge accumulation layer and the semiconductor substrate is substantially the same as that between the gate electrode and the semiconductor substrate. However, a film thickness of the gate insulation film between the sidewall charge accumulation layer and the semiconductor substrate may be thicker than that between the gate electrode and the semiconductor substrate.

In the first and the second embodiments, the source region 44 and the drain region 46 are formed after the insulation film 48 has been formed. However, the source region 44 and the drain region 46 may be formed after the sidewall charge accumulation layer 42 has been formed and before the sidewall insulation film 50 is formed, and in this case, conditions for the ion implantation and thermal processing are suitably selected so that the ends of the junctions of the source region 44 and the drain region 46 of the side of the gate electrode are positioned from below the sidewall charge accumulation layer 42 to below the sidewall insulation film 50.

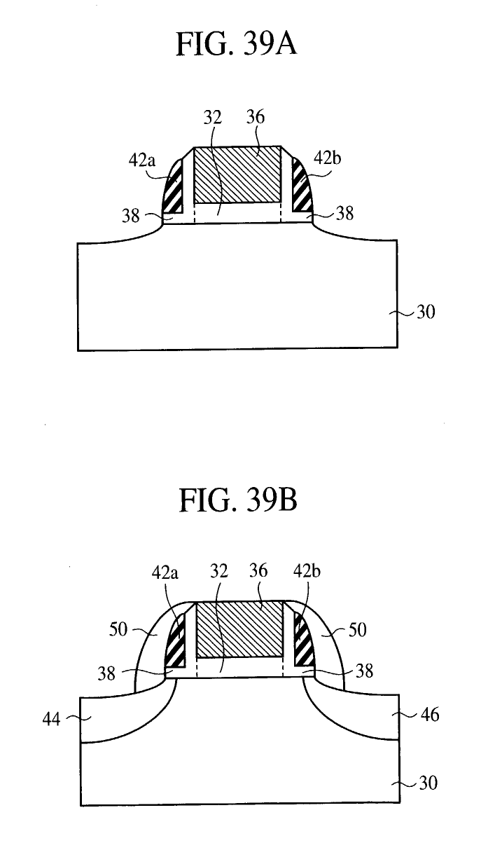

In the step of the first embodiment, which is shown in FIG. 7C, when the insulation film 38 is etched by dry etching, the surface of the silicon substrate 30 is often etched by several nanometers to tens nanometers as shown in FIG. 39A. FIGS. 39A and 38B are sectional views of the non-volatile semiconductor memory device according to a modification of the present invention in the steps of the method for fabricating the same, which show the method. When the silicon substrate 30 is etched in the step of FIG. 7C as shown in FIG. 39A, the configuration formed after the sidewall insulation film 50 has been formed is as shown in FIG. 39B.

In the third to the fifth embodiments, the film thickness between the sidewall charge accumulation layer and the semiconductor substrate is smaller than that of the insulation film between the gate electrode and the semiconductor substrate. However, the film thickness between the sidewall charge accumulation layer and the semiconductor substrate, and that of the insulation film between the gate electrode and the semiconductor substrate may be substantially the same. In the non-volatile semiconductor memory device according to the third to the fifth embodiments, the film thickness between the sidewall charge accumulation layer and the semiconductor substrate may be larger than that of the insulation film between the gate electrode and the semiconductor substrate.

The first to the fourth embodiments do not include the doped regions 56, 58 of a conduction type opposite to that of the source region 44 and the drain region 46 adjacent to the source region 44 and the drain region 46 (see FIG. 37) are not formed but may include the doped regions 56, 58.

In the fifth embodiment, the doped region 56 adjacent to the source region 44 and the doped region 58 adjacent to the drain region 46 are formed. However, it is possible that the doped region 56 alone, which is adjacent to the source region 44, may be formed, and the doped region 58 adjacent to the drain region 46 is not formed. It is also possible that the doped region 58 alone, which is adjacent to the drain region 46, is formed, and the doped region 56 adjacent to the source region 44 is not formed.

What is claimed is:

1. A non-volatile semiconductor memory device comprising:
a source region and a drain region formed in a semiconductor substrate;
a gate electrode formed on the semiconductor substrate between the source region and the drain region with a first insulation film formed between the gate electrode and the semiconductor substrate; and
a charge accumulation region of a dielectric material, which is formed on at least either of the side wall of the gate electrode on the side of the source region and the side wall of the gate electrode on the side of the drain region.

2. A non-volatile semiconductor memory device according to claim 1, wherein
a pair of the charge accumulation regions are formed independent of each other respectively on the side wall of the gate electrode on the side of the source region and on the side wall of the gate electrode on the side of the drain region.

3. A non-volatile semiconductor memory device according to claim 2, wherein
the ends of junctions of the source region and the drain region on the side of the gate electrode are spaced from a region of the semiconductor substrate immediately below the gate electrode.

4. A non-volatile semiconductor memory device according to claim 2, wherein
the ends of the junctions of the source region and the drain region on the side of the gate electrode are positioned below the charge accumulation regions.

5. A non-volatile semiconductor memory device according to claim 1, wherein
one of the ends of junctions of the source region and the drain region on the side of the gate electrode is spaced from a region of the semiconductor substrate immediately below the gate electrode; and
the other of the ends of the junctions of the source region and the drain region on the side of the gate electrode is positioned immediately below the gate electrode.

6. A non-volatile semiconductor memory device according to claim 5, wherein
said one of the ends of the junctions of the source region and the drain region on the side of the gate electrode is positioned below the charge accumulation region.

7. A non-volatile semiconductor memory device according to claim 1, wherein
the charge accumulation region is formed on the semiconductor substrate with a second insulation film formed between the charge accumulation region and the semiconductor substrate.

8. A non-volatile semiconductor memory device according to claim 7, wherein
the second insulation film is thinner than the first insulation film.

9. A method for fabricating a non-volatile semiconductor memory device comprising the steps of:
forming a first insulation film on a semiconductor substrate;
forming a gate electrode on the first insulation film;
forming charge accumulation regions of a dielectric material respectively on a pair of sidewalls of the gate electrode opposed to each other; and
implanting a dopant into the semiconductor substrate with the gate electrode and the charge accumulation regions as a mask to form a source region and a drain region with the ends of junctions thereof on the side of the gate electrode being spaced from a region of the semiconductor substrate immediately below the gate electrode.

10. A method for fabricating a non-volatile semiconductor memory device according to claim 9, wherein
in the step of forming the source region and the drain region, the source region and the drain region are formed with the ends of the junctions of the source region and the drain regions on the side of the gate electrode positioned below the charge accumulation regions.

11. A method for fabricating a non-volatile semiconductor memory device comprising the steps of:
forming a first insulation film on a semiconductor substrate;
forming a gate electrode on the first insulation film;
forming charge accumulation regions of a dielectric material on a pair of opposed side walls of the gate electrode; and
forming a source region and a drain region with one of the ends of junctions of the source region and the drain region on the side of the gate electrode spaced from a region of the semiconductor substrate immediately below the gate electrode and with the other of the ends of the junctions of the source region and the drain region on the side of the gate electrode positioned immediately below the gate electrode.

12. A method for fabricating a non-volatile semiconductor memory device according to claim 11, wherein
the step of forming the source region and the drain region includes the step of implanting a dopant into the semiconductor substrate with the gate electrode and the charge accumulation regions as a mask to form a first doped region with the end of the junction of the first doped region on the side of the gate electrode spaced from the region of the semiconductor substrate immediately below the gate electrode and the step of implanting a dopant into the semiconductor substrate with a mask which covers the semiconductor substrate on one side of the gate electrode to form a second doped region with the end of the junction of the second doped region on the side of the gate electrode positioned immediately below the gate electrode.

13. A method for fabricating a non-volatile semiconductor memory device according to claim 12, wherein
in the step of forming the source region and the drain region, the first doped region is formed with the end of the junction of the first doped region on the side of the gate electrode positioned below the charge accumulation region.

14. A method for fabricating a non-volatile semiconductor memory device according to claim 11, wherein
the step of forming source region and the drain region includes the step of implanting a dopant into the semiconductor substrate with a mask which covers the semiconductor substrate on one side of the gate electrode to form a first doped region with the end of the junction of the first doped region on the side of the gate electrode positioned immediately below the gate electrode; and the step of implanting a dopant into the semiconductor substrate with the gate electrode and the charge accumulation region as a mask to form a second doped region with the end of the junction of the second doped region on the side of the gate electrode spaced from the region of the semiconductor substrate immediately below the gate electrode.

15. A method for fabricating a non-volatile semiconductor memory device according to claim 14, wherein
in the step of forming the source region and the drain region, the second doped region is formed with the end of the junction of the second doped region on the side of the gate electrode positioned below the charge accumulation region.

16. A method for fabricating a non-volatile semiconductor memory device according to claim 11, further comprising after the step of forming the charge accumulation regions and before the step of forming the source region and the drain region:
the step of etching off one of said pair of charge accumulation regions.

17. A method for fabricating a non-volatile semiconductor memory device according to claim 9, which further comprises
the step of forming a second insulation film after the step of forming the gate electrode; and in which
in the step of forming the charge accumulation regions, the charge accumulation regions are formed on the semiconductor substrate with the second insulation film formed between the charge accumulation regions and the semiconductor substrate.

18. A method for fabricating a non-volatile semiconductor memory device according to claim 11, which further comprises
the step of forming a second insulation film after the step of forming the gate electrode forming step; and in which
in the step of forming the charge accumulation regions, the charge accumulation regions are formed on the semiconductor substrate with the second insulation film formed between the charge accumulation regions and the semiconductor substrate.

19. A method for fabricating a non-volatile semiconductor memory device according to claim 17, wherein
in the step of forming the second insulation, the second insulation film is formed thinner than the first insulation film.

20. A method for fabricating a non-volatile semiconductor memory device according to claim 18, wherein
in the step of forming the second insulation, the second insulation film is formed thinner than the first insulation film.

21. A method for fabrication a non-volatile semiconductor memory device according to claim 9, wherein
in the step of forming the charge accumulation regions, the charge accumulation regions are formed on the semiconductor substrate with the first insulation film formed between the charge accumulation regions and the semiconductor substrate.

22. A method for fabrication a non-volatile semiconductor memory device according to claim 11, wherein
in the step of forming the charge accumulation regions, the charge accumulation regions are formed on the semiconductor substrate with the first insulation film formed between the charge accumulation regions and the semiconductor substrate.

23. A method for fabricating a non-volatile semiconductor memory device according to claim 9, further comprising:
the step of forming a sidewall insulation film, covering the side walls of the gate electrode with the charge accumulation regions formed on after the step of forming the charge accumulation regions.

24. A method for fabricating a non-volatile semiconductor memory device according to claim 11, further comprising:
the step of forming a sidewall insulation film, covering the side walls of the gate electrode with the charge accumulation regions formed on after the step of forming the charge accumulation regions.
